(19) United States
(12) Patent Application Publication
(10) Pub. No.: US 2026/0032869 A1
(43) Pub. Date: Jan. 29, 2026

(54) CARTRIDGE BASED COOLING SYSTEM

(71) Applicant: INTEL CORPORATION, SANTA CLARA, CA (US)

(72) Inventors: Francesc Guim Bernat, Barcelona (ES); Karthik Kumar, Chandler, AZ (US); Uzair Qureshi, Chandler, AZ (US); Marcos Carranza, Portland, OR (US); Marek Piotrowski, Pepowo (PL)

(73) Assignee: INTEL CORPORATION, SANTA CLARA, CA (US)

(21) Appl. No.: 18/783,292

(22) Filed: Jul. 24, 2024

(51) Int. Cl. H05K 7/20

(52) U.S. Cl. CPC H05K 7/20772; H05K 7/20254

(57) ABSTRACT

A modular computing and cooling system is described. For example, an apparatus may comprise a physical interface for a modular computing and cooling system and an electronic cooling cartridge for insertion into the physical interface and removal from the physical interface. The electronic cooling cartridge may comprise an internal electronic component, an internal cooling component for thermal management of the internal electronic component using a cooling fluid, a set of internal connectors to connect the internal electronic component and the internal cooling component to an external electronic component and an external cooling component, respectively, of the modular computing and cooling system, and a closed container encapsulating the internal electronic component, the internal cooling component, and the set of internal connectors. Other embodiments are described and claimed.

### BACKGROUND

The increased growth and sophistication of artificial intelligence (AI) have driven design of larger and more powerful processors to manage the demands of large-scale language training programs required by AI developers. For example, semiconductor chips may contain billions of transistors (e.g., fin field-effect (FinFET) transistors) with decreasing die sizes that can execute tera floating point operations per second (TFLOP) of performance. With the increased demand for AI and the vast amounts of data needed to build AI services coupled with the increasing volume of data generated by other sources, such as edge computing and sixth generation (6G) cellular networks, the need for sustainable and scalable compute and storage solutions is becoming more urgent. However, an increase in data center capacity to fill this need is also resulting in an increase in energy consumption. This increase in data center energy demand is testing the limits of legacy thermal technologies. Effectively and efficiently cooling these chips presents new thermal challenges for legacy cooling technologies.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a perspective view of a semiconductor package in accordance with one embodiment.

FIG. 2 illustrates a semiconductor device in accordance with one embodiment.

FIG. 3 illustrates a modular computing and cooling system in accordance with one embodiment.

FIG. 4 illustrates an electronic cooling cartridge in accordance with one embodiment.

FIG. 5 illustrates a system for an electronic cooling cartridge in accordance with one embodiment.

FIG. 6 illustrates a system for an electronic cooling cartridge in accordance with one embodiment.

FIG. 7 illustrates a system for an electronic cooling cartridge in accordance with one embodiment.

FIG. 8 illustrates a system for an electronic cooling cartridge in accordance with one embodiment.

FIG. 9 illustrates a system for an electronic cooling cartridge in accordance with one embodiment.

FIG. 10 illustrates a logic flow in accordance with one embodiment.

FIG. 11 illustrates a logic flow in accordance with one embodiment.

FIG. 12 illustrates a computer-readable storage medium in accordance with one embodiment.

FIG. 13 illustrates a computing architecture in accordance with one embodiment.

FIG. 14 illustrates a communications architecture in accordance with one embodiment.

### DETAILED DESCRIPTION

Embodiments generally relate to liquid cooling techniques for thermal management of semiconductor devices. Embodiments particularly relate to a modular computing and cooling architecture for semiconductor devices for implementation in larger electronic devices, platforms or systems, such as server blades for a server rack of a data center to provide computing and storage services.

Data centers are complex systems in which multiple technologies and pieces of hardware interact to maintain safe and continuous operation of servers. With so many systems requiring power, the electrical energy used generates thermal energy. As the center operates, this heat builds and, unless removed, can cause equipment failures, system shutdowns, and physical damage to components. Much of this increased heat can be attributed to different processing units, collectively referred to as an “XPU,” where X stands for different letters depending on the context or specific function of the processing unit, which represents a shift towards more specialized, task-specific processors. Examples of an XPU include a central processing unit (CPU), graphics processing unit (GPU), data processing unit (DPU), vision processing unit (VPU), neural processing unit (NPU), infrastructure processing unit (IPU), tensor processing unit (TPU), and other processing units. Each new generation of XPU processor seems to offer greater speed, functionality, and storage, and chips are being asked to carry more of the load.

An increasingly urgent challenge is to find a new approach to cooling data centers that reaches beyond legacy thermal technologies, that is both energy-efficient and scalable, with the ultimate goal of enabling greater compute and data storage in an energy-efficient context. Effective operation of any processor depends on temperatures remaining within designated thresholds. The more power an XPU uses, the hotter it becomes. When a component approaches its maximum temperature, a device may attempt to cool the processor by lowering its frequency or throttling it. While effective in the short term, repeated throttling can have negative effects, such as shortening the life of the component.

A potential thermal management approach for cooling data centers is referred to as liquid cooling. Examples of liquid cooling techniques include direct liquid cooling, also known as direct-to-chip (DTC) cooling, and liquid immersion cooling. DTC cooling manages heat through the direct application of a coolant liquid onto the heat-generating components, such as processors and memory units. Unlike traditional air cooling that uses fans to circulate air around these components, direct liquid cooling involves circulating a coolant through a closed loop that absorbs heat directly from the components. This process significantly enhances cooling efficiency because liquids generally have higher heat capacity and conductivity than air. In direct liquid cooling systems, the coolant is pumped through cold plates that are in direct or indirect contact with the components. The heat from the components is transferred to the coolant. It is then circulated away and cooled through a heat exchanger. This method allows for more effective heat dissipation, enabling higher performance, increased component density, and potentially quieter operation due to the reduced need for fans. Direct liquid cooling is particularly beneficial in high-performance computing environments, like data centers and servers, as well as in high-end gaming personal computers and workstations, where the heat generated can exceed the capabilities of traditional air cooling methods.

In liquid immersion cooling systems, an immersion tank is filled with a dielectric fluid that partially or fully covers electronic components. The fluid dissipates heat generated by the electronic components. In open bath systems, an immersion tank is covered or uncovered and operates at atmospheric pressure. In closed bath systems, an immersion tank seals off the immersion fluid from the environment. The electronic components are fully submerged in a thermally conductive, electrically non-conductive liquid within a sealed enclosure. The closed bath immersion tank prevents the cooling liquid from coming into contact with the external environment. This enclosure helps in maintaining the integrity and cleanliness of the liquid, preventing contamination and evaporation.

Conventional liquid cooling systems suffer from various disadvantages. For example, current immersion cooling approaches typically require submerging servers in large fluid-filled tanks. While this approach works in many scenarios, such as edge installations, it can be cumbersome to implement in a traditional rack-oriented data center. Further, conventional liquid cooling systems face serviceability and replacement challenges due to the potential loss of immersion fluid while removing or inserting a rack-level computing system (e.g., blade, server, sled, etc.). As computing services grow across several thousands of locations in remote areas, there is a need to reduce costs by reducing onsite maintenance and serviceability as much as possible. Liquid cooling solutions, and immersion cooling in particular, can be used to mitigate high power consumption and thermal dissipation, while at the same time, offering the potential to drive down maintenance costs. One of the biggest contributors to maintenance costs is serviceability. When a processor or component goes bad, or when an immersion cooling solution leaks, maintenance and serviceability becomes significantly harder with immersion cooling solutions. As a result, the entire platform needs to be shipped back for maintenance or replacement. This is not a scalable approach and remains a large barrier to widespread adoption of the technology. Another problem is lack of standards in this space. Given there are currently no standards, a proprietary solution from one vendor cannot be swapped out for something from a different vendor. This makes manageability and maintenance very challenging, and vendor specific, thereby limiting the ability of these technologies to scale. Current solutions simply ship and replace the cooling solution. There is no drop in replacement capability at the edge today.

Embodiments address these and other challenges using a modular computing and cooling architecture. Embodiments are generally directed to a modular computing and cooling system comprising one or more modular computing and cooling components designed for insertion and removal from a larger device or system, such as a personal computer (PC), platform device such as a server blade, system device such as a server rack in a data center, and so forth. Some embodiments are particularly directed to a modular computing and cooling component such as an electronic cooling cartridge. The electronic cooling cartridge is a component of a larger electronic system comprising a system level cooling system for the electronic system. The electronic cooling cartridge includes a combination of module level electronic components and module level cooling components. When a module level electronic component or a module level cooling component needs servicing to perform such tasks as equipment maintenance, repair, update, or replacement with upgraded equipment, the electronic cooling cartridge is removed from the platform device or system device of the larger system. The serviced electronic cooling cartridge, or a replacement electronic cooling cartridge, is then re-inserted into the system to resume operations.

In one embodiment, for example, an electronic cooling cartridge comprises a closed container encapsulating a combination of internal electronic components and internal cooling components. The closed container is a hermetically sealed container that is completely airtight preventing the exchange of substances (e.g., liquids, solids, gases) between the inside of the closed container and the external environment. Non-limiting examples of internal electronic components include internal connectors, semiconductor dies, semiconductor chips, integrated circuit components, processors, processing circuitry, XPUs, controllers, memory chips, chipsets, circuit boards, interconnects, buses, switching fabrics, and so forth. Non-limiting examples of internal cooling components include internal fluid connectors, cold plates, fluid pipes to transport cooling fluid, manifolds, pumps, flow regulators, cooling units, cooling distribution units, heat exchangers, condensers, and so forth. The electronic cooling cartridge also comprises a set of internal operation connectors to connect the internal electronic components with external electronic components, such as interfaces, controllers, buses, interconnect fabrics, input/output (I/O) components, platform components, system components, and so forth. The electronic cooling cartridge further comprises a set of internal fluid connectors to connect internal cooling components with external cooling components, such as external fluid connectors, system level manifolds, fluid pipes to transport cooling fluid, cooling network units, cooling distribution units, fluid pumps, heat exchangers, condensers, and so forth. The internal operation connectors and internal fluid connectors allow for insertion of the electronic cooling cartridge into a larger computing and cooling system and removal of the electronic cooling cartridge from the larger computing and cooling system.

The modular computing and cooling architecture provides several technical advantages relative to conventional cooling solutions. For example, a modular computing and cooling component has physical dimensions and operational specifications (e.g., power, electrical, functionality, features, etc.) defined in accordance with one or more standards, such as device standards, industry standards, original equipment manufacturer (OEM) standards, technical standards, and so forth. When a modular computing and cooling component requires service or replacement, the modular computing and cooling component is removed from the system and it is serviced or replaced with another modular computing and cooling component with the same physical dimensions and operational specifications. In this manner, the modular computing and cooling architecture offers a module-level service model rather than a system-level model. In another example, a modular computing and cooling component may use different cooling techniques, such as a hybrid cooling technique combining the use of cold plates and different types of cooling fluids depending on thermal design power (TDP) requirements and environmental conditions supporting different climate conditions. For instance, a data center located in colder climates would require less cooling relative to a data center located in warmer climates that require more cooling. Further, some locations may shift between a colder climate and a warmer climate on a seasonal basis, thereby necessitating different electronic cooling modules with different cooling liquids during different seasons in a given year. To service an electronic cooling cartridge housing an XPU, the XPU is powered down, the cooling liquid is pumped out of the closed container, and it is ready for safe removal from the system chassis. For reinsertion, a system operator can insert the empty closed container into the system chassis, access a software interface for the system chassis to select a cooling liquid for the empty closed container. A fluid pump moves the liquid into the cooling components of the cartridge, and the system powers on the XPU to become operational once again.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), fifth generation (5G) and sixth generation (6G) communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages having cold plates and manifolds over package substrates that have a plurality of semiconductor dies, where each semiconductor die is cooled with one or more liquid cooling paths.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

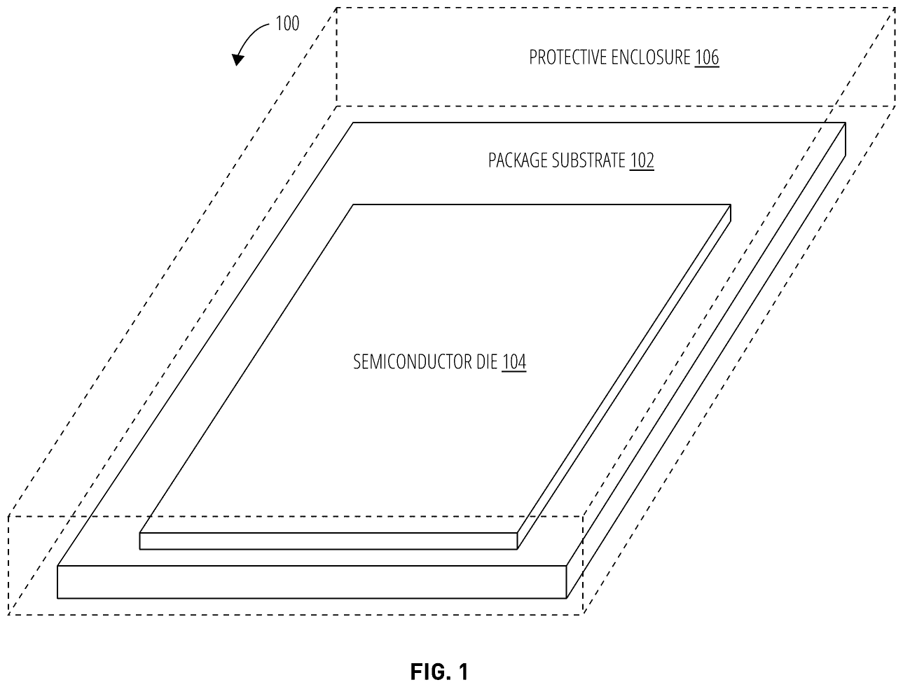

FIG. 1 is an example of a semiconductor package 100 suitable for use with an electronic cooling cartridge of a modular computing and cooling system as described herein. As depicted in FIG. 1, the semiconductor package 100 comprises core packaging components such as a package substrate 102 and one or more semiconductor dies 104 mounted on the package substrate 102, both of which are encapsulated by a protective enclosure 106. It is worthy to note that a semiconductor package 100 may include additional packaging components not shown in FIG. 1. For example, a semiconductor package 100 typically includes layers of conductive traces, electrical connectors, and support structures for the semiconductor die 104. These components are not shown for purposes of clarity and not limitation. Embodiments are not limited to the example shown in FIG. 1.

The semiconductor package 100 comprises a protective enclosure 106 for one or more semiconductor dies 104 mounted on a package substrate 102. The protective enclosure 106 provides electrical connections to external circuits and mechanical protection. It facilitates the integration of the semiconductor die 104 into larger electronic devices and circuit boards. The semiconductor package 100 also plays a role in heat dissipation, helping to remove the heat generated by the semiconductor die 104 and maintain optimal operating conditions. Examples of different types of semiconductor packages 100 include a Dual In-line Package (DIP), a Ball Grid Array (BGA), and a Quad Flat Package (QFP). Each semiconductor package 100 is designed to meet different requirements in terms of size, performance, and application. The choice of a semiconductor package 100 directly affects reliability, performance, cost, and size of an electronic device.

The package substrate 102 of the semiconductor package 100 acts as an intermediary platform between the semiconductor die 104 and external circuitry. An examples of package substrate 102 is a printed circuit board (PCB). It serves as a foundation on which the semiconductor die 104 is mounted and provides a pathway for electrical signals from the semiconductor die 104 to reach the external connections of the semiconductor package 100. The package substrate 102 is engineered from materials like ceramic, organic resin, or silicon, and it features multiple layers that include conductive traces and vias to facilitate electrical connectivity. These layers are meticulously designed to manage signal integrity, power distribution, and thermal performance. The package substrate 102 not only supports mechanical integrity and enhances the electrical performance of the semiconductor client device 802 but also plays a vital role in heat dissipation, ensuring the longevity and reliability of the semiconductor die 104 by maintaining thermal conditions within operational limits. In one embodiment, the package substrate 102 is a PCB made of an FR-4 glass epoxy base with thin copper foil laminated on both sides. In some embodiments, the PCB is a multilayer PCB, with a pre-impregnated (pre-preg) layer and copper foil used to make additional layers. For example, the multilayer PCB may include one or more dielectric layers, where each dielectric layer can be a photosensitive dielectric layer. In some embodiments, holes may be drilled in the package substrate 102. The package substrate 102 may also include conductive layers that comprise conductive (or copper) traces, pads, vias, via pads, planes, and/or holes.

The semiconductor die 104 is a relatively small, thin piece of semiconductor material, typically silicon, that has been carefully fabricated to contain an integrated circuit (IC). The IC comprises numerous electronic components such as transistors, diodes, and resistors, all intricately patterned on the semiconductor substrate through processes like photolithography, etching, and doping. These components are interconnected to perform various electronic functions, ranging from simple logic operations to complex computational tasks. The semiconductor die 104 is encased in the protective enclosure 106 to form a complete electronic device, ensuring its functionality and reliability in a wide range of applications, including computers, smartphones, and various electronic systems. In an embodiment, the semiconductor die 104 may be implemented as a microprocessor, a microelectronic device, a semiconductor chip, a chiplet, an integrated circuit (IC), a circuit, a processor, processing circuitry, circuitry, an XPU, a controller, a platform controller hub (PCH), a memory, a field-programmable gate array (FPGA), power management IC, electronic control unit (ECU) for an autonomous vehicle, or any other semiconductor device.

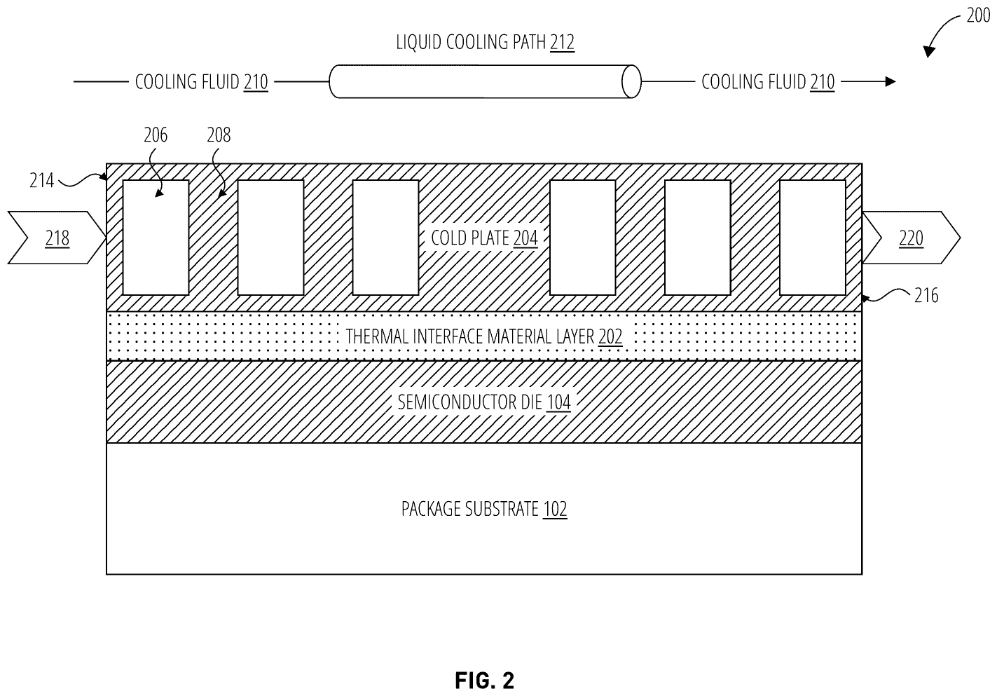

Additionally, in some embodiments as shown below in FIG. 2, thermal components such as a cold plate, a manifold, and thermal interface material (TIM) layer may be disposed over the top surface of the semiconductor die 104 and/or the package substrate 102.

FIG. 2 illustrates a cross-sectional view of a semiconductor device 200 of the semiconductor package 100. The semiconductor device 200 depicts a cross-sectional view of the package substrate 102 and the semiconductor die 104 mounted on the package substrate 102 of the semiconductor package 100. In one embodiment, as illustrated in FIG. 2, the semiconductor device 200 does not use a protective enclosure 106. However, other embodiments may optionally use a protective enclosure 106 for the semiconductor device 200 for a given implementation. Embodiments are not limited in this context.

In addition to the package substrate 102 and the semiconductor die 104, the semiconductor device 200 comprises additional thermal management components, such as a thermal interface material layer and a cold plate. The thermal management components of the semiconductor package 100 implement a liquid cooling solution that enables module level cooling of the semiconductor die 104 and/or the entire semiconductor package 100. For example, the semiconductor package 100 may implement a liquid cooling technique such as direct liquid cooling and/or liquid immersion cooling. Direct liquid cooling, also known as direct-to-chip (DTC) cooling, manages heat through the direct application of a cooling fluid 210 onto the heat-generating components, such as semiconductor dies 104. Liquid immersion cooling immerses some or all of the semiconductor die 104 within the cooling fluid 210. The cooling fluid 210 flows throughout the semiconductor package 100 along one or more liquid cooling paths, such as a liquid cooling path 212.

As described herein, a cooling fluid 210 may transfer heat from the semiconductor die 104 to the cold plate 204 which dissipates heat from the heated liquid into the ambient, or another separate liquid cooling component or system. Examples of cooling fluids 210 include engineered fluids such as 3M™ Novec™ and Fluorinert™, synthetic oils, and specially formulated dielectric fluids. These fluids have high thermal conductivity and are electrically insulating. Two parameters of cooling fluid 210 to consider when choosing a cooling fluid 210 for use in a particular cooling implementation are its flammability and global warming potential (GWP) number, with a lower GWP number indicating that a material contributes less to global warming. Some synthetic single-phase cooling liquids (e.g., Novec fluids) have good thermal performance but also have a high GWPs. As there are worldwide efforts to phase out the use of greenhouse gases, such as hydrofluorocarbons, there is interest in using non-GWP or low-GWP materials (e.g., materials having a GWP<1) where possible. The liquid cooling technologies disclosed herein can provide for the liquid cooling of electronic devices and systems comprising high-performance IC components using non-flammable and/or non-GWP or low-GWP fluids. The use of such technologies can aid large cloud service providers (CSPs), high-performance computing (HPC) system vendors, and other entities that may begin to increasingly rely on liquid cooling in data centers to meet defined environmental sustainability (e.g., carbon-neutral, carbon-negative) goals.

In one embodiment, the cooling fluid 210 flowing through the liquid cooling path 212 is a non-electric-conductive, non-ionic, and non-reactive liquid (e.g., a fluorinated liquid). In another embodiment, the fluid may be water when the semiconductor die 104 is surrounded with an insulated material. In some embodiments, the cooling fluid 210 may be a fluorinated liquid type and/or a freon liquid type. Examples of a fluorinated liquid type may include without limitation FC-3283, FC-40, FC-43, FC-72, FC-75, FC-78, and FC-88. In one embodiment, for example, the freon liquid type may include freon-C-51-12, freon-E5, or freon-TF. Embodiments are not limited to these examples.

As depicted in semiconductor device 200, the cold plate 204 is disposed over a top surface of the semiconductor die 104 mounted on the package substrate 102. The cold plate 204 includes a plurality of openings 206, a plurality of channels 208 (or micro-channels), an inlet opening 214, and an outlet opening 216. The cold plate 204 channels a cooling fluid 210 from an inlet opening 214 through the channels 208 inside of the cold plate 204, where the fluid may flow through the openings 206 and cool the channels 208 within the cold plate 204, to an outlet opening 216. The outlet opening 216 releases the cooling fluid 210 from the cold plate 204 to one or more other liquid cooling components, such as a pump, a filter, a remote heat exchanger, a chiller, and so forth. The liquid cooling components may pump, filter, dissipate heat from, and chill the cooling fluid 210 before the cooling fluid 210 is recirculated back to the inlet opening 214 of the cold plate 204. For example, the liquid cooling path 212 may include an input flow 218 and an output flow 220. The input flow 218 may direct the cooling fluid 210 into the inlet opening 214 of the cold plate 204, through the channels 208 of the cold plate 204 as the chilled fluid cools the semiconductor die 104, and away from the semiconductor die 104 with the output flow 220 through the outlet opening 216 of the cold plate 204. The cooling fluid 210 may then be forwarded to a pump and/or a filter (or other components) before recirculating back to the inlet opening 214 of the cold plate 204.

The cooling liquid flowing through the cold plate 204 transfers the heat generated by the semiconductor die 104 onto the cold plate 204, which dissipates heat from the heated liquid into the ambient, or another separate liquid cooling component or system. In one embodiment, for example, the cold plate 204 may be formed of a highly thermally conductive material, such as copper, aluminum, or the like. In one embodiment, for example, the cold plate 204 may have a thickness of approximately 5 millimeters (mm) to 20 mm.

In one embodiment, a TIM layer 202 may be disposed on the semiconductor die 104 to thermally and/or mechanically couple the semiconductor die 104 to the cold plate 204. Examples for the TIM layer 202 may comprise without limitation a polymer TIM (PTIM), an epoxy, a liquid phase sintering (LPS) paste, a solder paste, a solder TIM (STIM), and/or any other type of thermal interface material. Note that the TIM layer 202 may need to be a material compatible with the applicable liquids described herein.

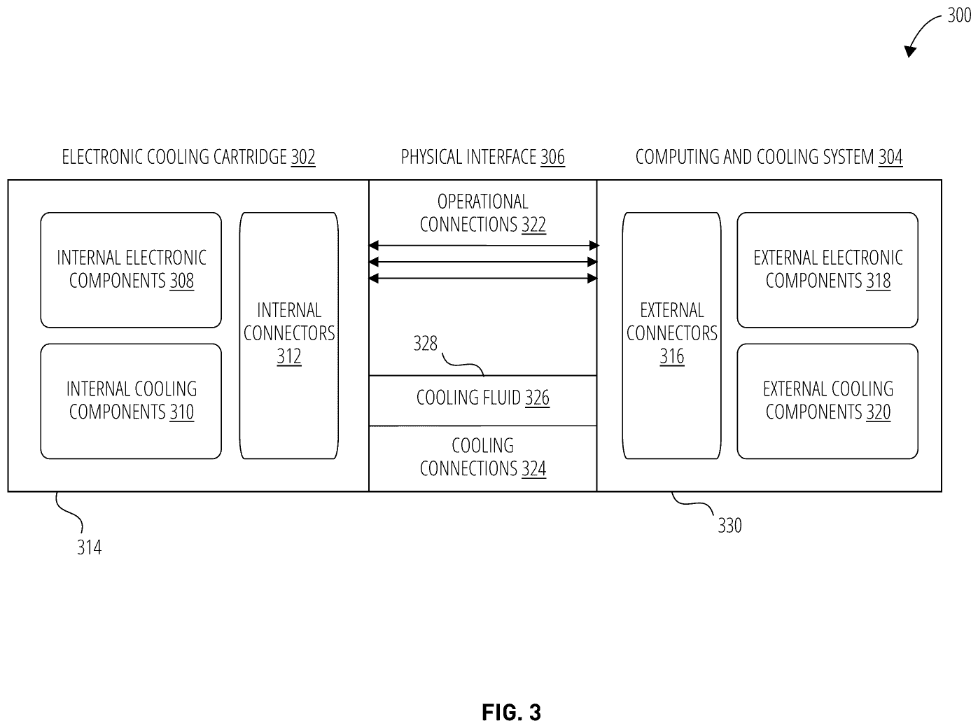

FIG. 3 illustrates a modular computing and cooling system 300. The modular computing and cooling system 300 is an example of a system implementing a modular computing and cooling architecture in accordance with various embodiments as described herein.

As previously described, embodiments are generally directed to a modular computing and cooling system 300 comprising one or more modular computing and cooling components designed for insertion and removal from a larger device or system, such as a personal computer (PC), platform device such as a server blade, system device such as a server rack in a data center, and so forth.

As depicted in FIG. 3, the modular computing and cooling system 300 comprises an electronic cooling cartridge 302 physically and operationally connected to a larger device or system, such as a computing and cooling system 304 by a physical interface 306. The electronic cooling cartridge 302 is a component of a larger computing and cooling system 304 comprising a system level cooling system for the electronic system. The electronic cooling cartridge 302 includes a combination of module level electronic components and module level cooling components. When a module level electronic component or a module level cooling component needs servicing to perform such tasks as equipment maintenance, repair, update, or replacement with upgraded equipment, the electronic cooling cartridge 302 is removed from the computing and cooling system 304. The serviced electronic cooling cartridge 302, or a replacement electronic cooling cartridge 302, is then re-inserted into the computing and cooling system 304 to resume operations.

The modular computing and cooling system 300 includes a physical interface 306 for the computing and cooling system 304. The physical interface 306 provides a set of operational connections 322 between the electronic cooling cartridge 302 and the computing and cooling system 304. The operational connections 322 communicate control and data signals between the electronic cooling cartridge 302 and the computing and cooling system 304. For the operational connections 322, the physical interface 306 utilizes various mediums to facilitate transmission of electrical signals or light signals, such as electrical connection mediums and optical connection mediums. Non-limiting examples of electrical connection mediums include copper wires or cables, twisted pair cables, coaxial cables, PCBs, traces, vias, and so forth. Non-limiting examples of optical connection mediums include fiber optic cables, plastic optical fibers, waveguides, free-space optical communications, and so forth. Both electrical and optical mediums have their specific applications, advantages, and limitations, chosen based on factors such as the required transmission speed, distance, cost, and environmental conditions. The physical interface 306 also provides a set of cooling connections 324 between the electronic cooling cartridge 302 and the computing and cooling system 304. The cooling connections 324 transport cooling fluid 326 between the electronic cooling cartridge 302 and the computing and cooling system 304. For the cooling connections 324, the physical interface 306 utilizes a fluid pipe to facilitate transport of the cooling fluid 326.

The computing and cooling system 304 comprises a chassis 330 housing a set of external electronic components 318 and a set of external cooling components 320. Non-limiting examples of external electronic components 318 include interfaces, controllers, buses, interconnect fabrics, input/output (I/O) components, platform components, system components, power supplies, batteries, and so forth. Non-limiting examples of external cooling components 320 include external fluid connectors, system level manifolds, fluid pipes to transport cooling fluid, cooling network units, cooling distribution units, fluid pumps, heat exchangers, condensers, and so forth. The external electronic components 318 and the external cooling components 320 are accessed via a set of external connectors 316 corresponding to similar connectors and media of the physical interface 306.

The modular computing and cooling system 300 also includes an electronic cooling cartridge 302 for insertion into the physical interface 306 and removal from the physical interface 306. The electronic cooling cartridge 302 includes a set of internal electronic components 308, a set of internal cooling components 310 for thermal management of the internal electronic components 308 using a cooling fluid 210, a set of internal connectors 312 to connect the internal electronic components 308 and the internal cooling components 310 to a set of external electronic components 318 and a set of external cooling components 320, respectively, of the computing and cooling system 304, and a closed container 314 encapsulating the set of internal electronic components 308, the set of internal cooling components 310, and the set of internal connectors 312.

In one embodiment, for example, an electronic cooling cartridge 302 comprises a closed container 314 encapsulating a combination of internal electronic components and internal cooling components. The closed container 314 is a hermetically scaled container that is completely airtight preventing the exchange of substances (e.g., liquids, solids, gases) between the inside of the closed container 314 and an external operating environment.

In one embodiment, for example, a set of internal electronic components 308 comprises internal connectors, semiconductor dies, semiconductor chips, integrated circuit components, processors, processing circuitry, XPUs, controllers, memory chips, chipsets, circuit boards, interconnects, buses, switching fabrics, power supplies, batteries, and so forth. In one embodiment, for example, a set of internal connectors 312 comprise connectors to connect the internal electronic components 308 with external electronic components 318 of the computing and cooling system 304, such as interfaces, controllers, buses, interconnect fabrics, input/output (I/O) components, platform components, system components, and so forth.

In one embodiment, for example, a set of internal cooling components 310 comprises internal fluid connectors, cold plates, fluid pipes to transport cooling fluid, manifolds, pumps, flow regulators, cooling units, cooling distribution units, heat exchangers, condensers, and so forth. In one embodiment, for example, a set of internal connectors 312 comprises a set of internal fluid connectors to connect internal cooling components 310 with external cooling components 320, such as external fluid connectors, system level manifolds, fluid pipes to transport cooling fluid, cooling network units, cooling distribution units, fluid pumps, heat exchangers, condensers, and so forth. The internal operation connectors and internal fluid connectors allow for insertion of the electronic cooling cartridge 302 into the larger computing and cooling system 304 and removal of the electronic cooling cartridge 302 from the larger computing and cooling system 304.

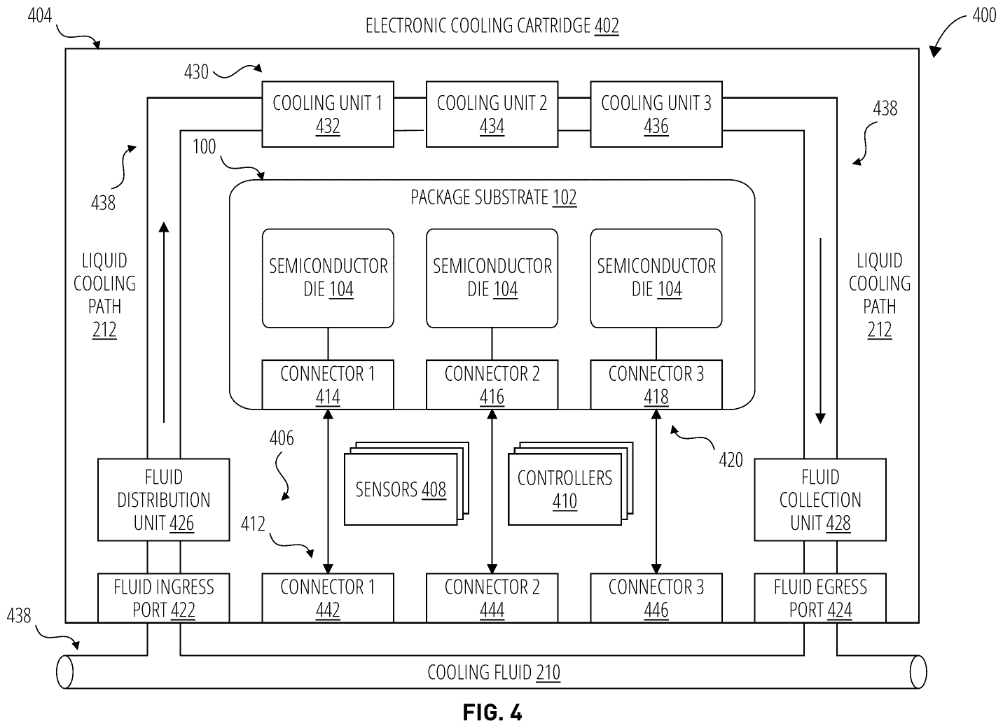

FIG. 4 illustrates an apparatus 400. The apparatus 400 comprises an example of an electronic cooling cartridge 402 suitable for use with the modular computing and cooling system 300. Specifically, the electronic cooling cartridge 402 comprises an example for the electronic cooling cartridge 302 implementing an N number of semiconductor dies 104 from the semiconductor package 100, with or without the protective enclosure 106, where N represents any positive integer. The electronic cooling cartridge 402 also comprises a set of internal electronic components 308 and a set of internal cooling components 310.

As depicted in apparatus 400, the electronic cooling cartridge 402 comprises a closed container 404. In one embodiment, for example, the closed container 404 is a hermetically sealed container that is completely airtight preventing the exchange of substances (e.g., liquids, solids, gases) between the inside of the closed container and the external environment. The closed container 404 encapsulates a set of internal electronic components 308 and a set of internal cooling components 310 mounted on or proximate to a cartridge substrate 406. The cartridge substrate 406 may be implemented using the same or similar examples given for the package substrate 102 of the semiconductor package 100. In one embodiment, for example, the cartridge substrate 406 is a PCB.

The internal electronic components 308 may include a set of one or more controllers 410. The controllers 410 may control operations for one or more of the internal electronic components 308 and/or the internal cooling components 310. For example, the controllers 410 manage the operation of the cooling system to optimize performance and ensure efficient heat dissipation. It regulates various parameters of the liquid cooling system, such as pump speed to control the flow rate of the coolant to balance cooling efficiency and noise levels; fan speed to adjust the speed of fans attached to radiators or heat exchangers to control airflow and noise, based on the temperature of the coolant or the components being cooled; uses sensors 408 to monitor temperatures at critical points in the system, such as the liquid coolant, the radiator, and the components being cooled (like CPUs or GPUs); manage RGB lighting on components like fans, pumps, and reservoirs; and other management operations. The controllers 410 can operate based on system management commands or control directives, preset profiles, or dynamically adjust parameters of the cooling system in real-time based on feedback from sensors 408, achieving optimal cooling efficiency, noise levels, and power consumption. Some controllers 410 offer user interfaces, allowing users to customize settings according to their preferences or specific application requirements.

The internal electronic components 308 may include a set of one or more sensors 408 to monitor various properties and attributes of the internal electronic components and/or internal cooling components of the electronic cooling cartridge 402. In the liquid cooling system of the electronic cooling cartridge 402, various sensors 408 are employed to ensure efficient operation, safety, and performance monitoring. For example, the sensors 408 may include temperature sensors designed to measure the temperature of the liquid coolant and components being cooled, such as the semiconductor dies 104 and other electronic components. Common types of temperature sensors include thermocouples, thermistors, and resistance temperature detectors (RTDs). The sensors 408 may include flow sensors designed to measure a flow rate of the cooling fluid 210 in the system, ensuring it is circulating properly. Examples include turbine flow sensors, ultrasonic flow sensors, and paddlewheel sensors. The sensors 408 may include pressure sensors designed to measure the pressure of the cooling fluid 210 within the electronic cooling cartridge 402. This is important for detecting leaks, blockages, or pump failures. Common types include piezoelectric pressure sensors and strain gauge pressure sensors. The sensors 408 may include level sensors designed to detect a coolant level within a reservoir or tank, ensuring the system has enough cooling fluid 210 to function properly. Types include capacitive level sensors, ultrasonic level sensors, and float level sensors. The sensors 408 may include pH sensors designed to monitor an acidity or alkalinity of the cooling fluid 210 to prevent corrosion-related damage. The sensors 408 may include conductivity sensors designed to measure the electrical conductivity of the cooling fluid 210 This can be important for detecting contamination or the concentration of additives in the cooling fluid 210. The sensors may include temperature difference sensors designed to measure a temperature difference across the cooling system to assess its efficiency. Each of the sensors 408 plays a role in monitoring and controlling a liquid cooling system, contributing to its effectiveness and longevity. Embodiments are not limited to these examples.

The internal electronic components 308 may include the semiconductor package 100, such as the package substrate 102 and one or more semiconductor dies 104. In one embodiment, for example, the entire semiconductor package 100 is mounted on the cartridge substrate 406. In one embodiment, for example, only the package substrate 102 and the one or more semiconductor dies 104 are mounted on the cartridge substrate 406 without the protective enclosure 106. In one embodiment, for example, only the one or more semiconductor dies 104 are mounted on the cartridge substrate 406 without the package substrate 102 or the protective enclosure 106. Embodiments are not limited in this context.

The semiconductor package 100 further comprises a set of internal operation connectors, such as connectors 420, including a connector 1 414, a connector 2 416, and a connector 3 418 corresponding to a first semiconductor die 104, a second semiconductor die 104, and a third semiconductor die 104 (e.g., N=3), respectively. The connector 1 414, connector 2 416, and connector 3 418 correspond to a connector 1 442, a connector 2 444, and a connector 3 446, respectively, of the electronic cooling cartridge 402. The internal operation connectors attach to a set of physical wires or traces embedded in the package substrate 102 and/or the cartridge substrate 406 that provide a pathway for electrical and/or optical signals from the semiconductor dies 104 to reach external connections of the electronic cooling cartridge 402. Examples of connectors include electrical connectors, optical connectors, I/O connectors, power connectors, management connectors, and other types of connectors. Embodiments are not limited to these examples.

The closed container 404 further encapsulates a set of internal cooling components 310 mounted to the cartridge substrate 406. For example, the internal cooling components include a fluid ingress port 422, a fluid distribution unit 426, a fluid collection unit 428, a fluid egress port 424, a set of fluid pipes 438, and a set of cooling units 430. The cooling unit 430 may include a cooling unit 1 432, a cooling unit 2 434, and a cooling unit 3 436 for cooling the first semiconductor die 104, the second semiconductor die 104, and the third semiconductor die 104, respectively.

The fluid distribution unit 426 and the fluid collection unit 428 circulate the cooling fluid 210 throughout the electronic cooling cartridge 402 along the liquid cooling path 212 through a set of fluid pipes 438. In various embodiments, the fluid pipes 438 may be partially or fully mounted on the cartridge substrate 406, embedded within the cartridge substrate 406, floating above the cartridge substrate 406, or some combination thereof. The fluid distribution unit 426 receives the cooling fluid 210 from the fluid ingress port 422 and it distributes the cooling fluid 210 to the cooling units 430 for collection by the fluid collection unit 428. The fluid collection unit 428 then sends the heated liquid to the fluid egress port 424 for thermal management by external cooling components 320 outside of the closed container 404 in an open-loop system. Additionally, or alternatively, the heated liquid can be re-circulated through internal thermal management components similar to the external cooling components 320 implemented as part of the closed container 404 in a closed-loop system. Embodiments are not limited in this context.

The fluid distribution unit 426 is a component designed to efficiently manage a flow and distribution of cooling fluid 210 throughout the electronic cooling cartridge 402. This unit functions as a control center for the coolant movement, directing it from a cooling source, like a fluid ingress port 422 connected to a radiator or chiller, to the specific components that require cooling, such as the semiconductor dies 104. The fluid distribution unit 426 comprises one or more pumps to propel the cooling fluid 210, valves to control the flow direction of the cooling fluid 210, and channels or pathways that distribute the cooling fluid 210 to various parts of the electronic cooling cartridge 402 while ensuring an even and optimal cooling effect. The fluid distribution unit 426 assists in maintaining a balance between the cooling capacity and a thermal load of the semiconductor dies 104 contained within the electronic cooling cartridge 402, thereby achieving efficient heat removal, minimizing temperature spikes, and ensuring the reliable operation of the semiconductor dies 104.

The fluid collection unit 428 is a component designed to gather and hold the cooling fluid 210 after it has absorbed heat from the semiconductor dies 104. Once the cooling fluid 210 circulates through the electronic cooling cartridge 402, absorbing heat from the hot components, it is directed towards the fluid collection unit 428. This unit acts as a reservoir, temporarily storing the heated fluid before it is directed to a cooling sink, such as a fluid egress port 424 connected to a cooling mechanism like a radiator or a heat exchanger to dissipate the absorbed heat to the surrounding environment before it is recirculated back through the electronic cooling cartridge 402. The fluid collection unit 428 ensures a consistent and uninterrupted flow of cooling fluid 210 throughout the electronic cooling cartridge 402, helps in maintaining the optimal level of cooling fluid 210 in the electronic cooling cartridge 402, and assists in managing thermal dynamics for the electronic cooling cartridge 402 by facilitating the efficient removal and recirculation of the cooling fluid 210. Its design ensures temperature stability and reliability of the semiconductor dies 104.

The fluid distribution unit 426 and/or the fluid collection unit 428 may be controlled by external commands received from a system management application via a management connector for the electronic cooling cartridge 402. For instance, a system operator or an automated system may generate command and control directives for the liquid cooling system of the electronic cooling cartridge 402 in response to measurements received from the one or more sensors 408. Examples of external commands include a set of control directives, such as a control directive to the fluid distribution unit 426 to release the cooling fluid 210 from the fluid ingress port 422 into the fluid pipes 438, a control directive to the fluid collection unit 428 to drain the cooling fluid 210 from the fluid pipes 438 to the fluid egress port 424, a control directive to control types of the cooling fluid 210 to release into the fluid pipes 438 or drain from the fluid pipe 438, a control directive to control an amount of the cooling fluid 210 to release into the fluid pipe 438 or draft from the fluid pipe 438, and other management operations for the cooling components of the electronic cooling cartridge 402.

The cooling unit 430 is a component designed to cool (or remove heat from) the semiconductor die 104. The cooling unit 430 may implement different types of liquid cooling techniques to cool the semiconductor die 104. Examples of liquid cooling techniques include direct liquid cooling and liquid immersion cooling.

In some embodiments, the cooling unit 430 may implement direct liquid cooling, also known as direct-to-chip (DTC) cooling, to manage heat through the direct application of a coolant liquid onto the heat-generating components, such as processors and memory units. In one embodiment, for example, the cooling unit 430 may implement direct die cooling which involves directly attaching a cooling block or cold plate 204 to the semiconductor die 104, as described with reference to FIG. 2. The cooling fluid 210 flows directly over the semiconductor die 104, absorbing heat more efficiently than indirect methods. This technique ensures minimal thermal resistance between the semiconductor die 104 and the cooling fluid 210, providing effective cooling for high-power devices. In one embodiment, for example, the cooling unit 430 may implement microchannel cooling. Microchannel coolers are integrated into the semiconductor package 100 or directly onto the semiconductor die 104, featuring very narrow, micro-scale channels through which cooling fluid 210 flows, as described with reference to FIG. 2. This method increases the heat transfer surface area in contact with the semiconductor die 104, significantly enhancing heat removal from the semiconductor die 104. In one embodiment, for example, the cooling unit 430 may implement indirect liquid cooling. In this approach, the cooling fluid 210 does not directly contact the semiconductor die 104. Instead, it circulates through a heat exchanger or cold plate attached to the package that houses the semiconductor die 104. While not as efficient as direct cooling methods, it offers a safer and cleaner option by reducing the risk of coolant leakage onto the semiconductor die 104.

In some embodiments, the cooling unit 430 may implement liquid immersion cooling which fills the closed container 404 with cooling fluid 210. The internal electronic components, such as the semiconductor dies 104, are partially or fully submerged in a thermally conductive, electrically non-conductive liquid within the closed container 404. The closed container 404 prevents the cooling fluid 210 from coming into contact with the external environment. The closed container 404 helps in maintaining the integrity and cleanliness of the cooling fluid 210, preventing contamination and evaporation.

In one embodiment, for example, the 430 may implement jet impingement cooling. The cooling fluid 210 is forcefully sprayed onto the semiconductor die 104 or its encapsulating package through nozzles, allowing for highly effective heat transfer. The impinging jets of cooling fluid 210 enhance the cooling effect by actively removing heat from the surface of the semiconductor die 104, making it suitable for high-heat-flux applications.

In one embodiment, for example, the cooling unit 430 may implement a form of immersion cooling. The cooling unit 430 and/or the fluid distribution unit 426 may flood the entire closed container 404 with the cooling fluid 210 to partially or completely immerse the semiconductor package 100 in the cooling fluid 210. For example, the cooling unit 430 and/or the fluid distribution unit 426 may have a valve to release the cooling fluid 210 into the closed container 404 in response to a command from the system management application. Heat from the semiconductor die 104 is efficiently transferred to the surrounding liquid. This method is gaining popularity for cooling high-density computing hardware and offers the advantage of cooling multiple components simultaneously.

When the cooling unit 430 implements jet impingement cooling or liquid immersion cooling, the fluid collection unit 428 may periodically, or in response to a system management command, collect the cooling fluid 210 from the closed container 404 via a pump or suction component from the electronic cooling cartridge 402 and send the collected cooling fluid 210 to the fluid egress port 424.

The electronic cooling cartridge 402 may implement different types of cooling units 430, where each cooling unit 430 implements a liquid cooling technique that is tailored to the specific thermal management needs of the semiconductor dies 104, considering factors such as power density, size constraints, and reliability requirements of the semiconductor dies 104. Embodiments are not limited to these examples.

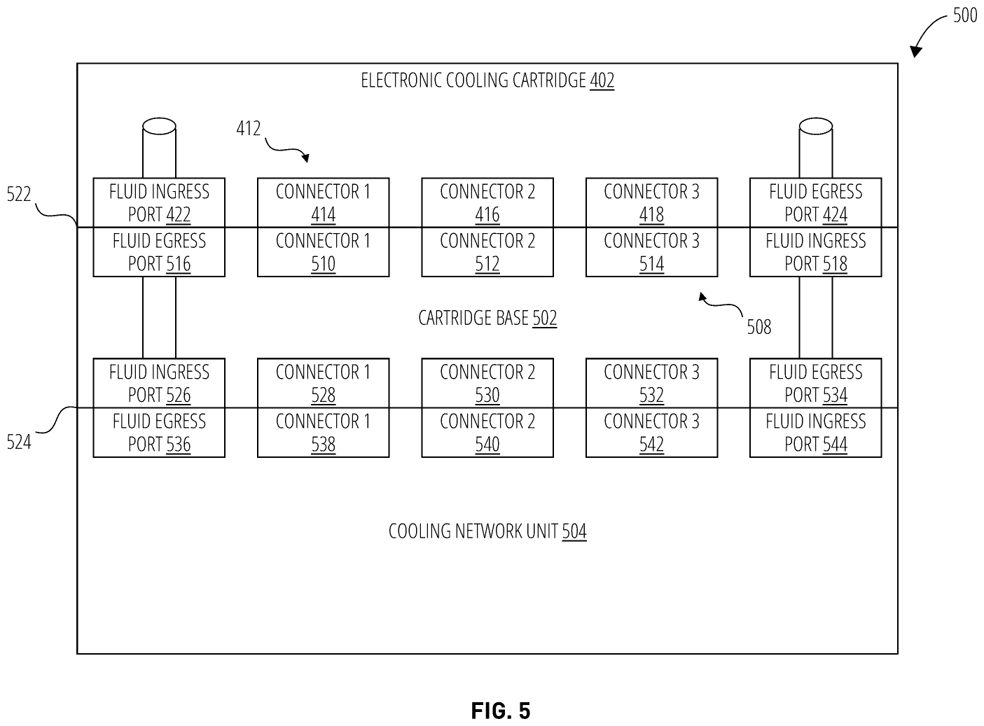

FIG. 5 illustrates a system 500. The system 500 comprises an example implementation for the electronic cooling cartridge 402 connected to an external liquid cooling system of a larger device, platform, or system.

As depicted in FIG. 5, the system 500 comprises an electronic cooling cartridge 402 physically and operably coupled to a cartridge base 502. The cartridge base 502 operates as intermediate component between the electronic cooling cartridge 402 and a cooling network unit 504 of an external device, platform, or system. The cartridge base 502 incorporates various interface components to connect the internal electronic components and internal cooling components with corresponding external electronic components and external cooling components of the cooling network unit 504. For example, the internal operation connectors of the electronic cooling cartridge 402 such as the connector 1 414, the connector 2 416, and the connector 3 418 correspond to external operation connectors such as a connector 1 510, a connector 2 512, and a connector 3 514, respectively, of the cartridge base 502. Similarly, the internal cooling connectors of the electronic cooling cartridge 402 such as the fluid ingress port 422 and the fluid egress port 424 correspond to external fluid connectors such as a fluid egress port 516 and a fluid ingress port 518, respectively, of the cartridge base 502. The external operation connectors such as connector 1 510, connector 2 512, and connector 3 514 of the cartridge base 502 correspond to a connector 1 538, a connector 2 540, and a connector 3 542, respectively, of the cooling network unit 504. Similarly, the external fluid connectors such as fluid ingress port 526 and the fluid egress port 534 of the cartridge base 502 correspond to a fluid egress port 536 and a fluid ingress port 544, respectively, of the cooling network unit 504.

The cartridge base 502 also has a form factor with a physical size, geometry, and interfaces that match those of the electronic cooling cartridge 402 on side A 522 of the cartridge base 502, as well as the cooling network unit 504 on side B 524 of the cartridge base 502. When the electronic cooling cartridge 402 has a different form factor or interfaces from those used by the cooling network unit 504 of the larger device or system, a cartridge base 502 is selected to match the electronic cooling cartridge 402 and the cooling network unit 504 to ensure physical and operational connections between the electronic cooling cartridge 402 and the cooling network unit 504 of the larger device or system, and vice-versa. The configurability of the cartridge base 502 allows electronic cooling cartridges 402 from one original equipment manufacturer (OEM) to interoperate with devices and systems from another OEM, and vice-versa, thereby offering flexibility to different OEMs and liquid cooling technology developers and providers.

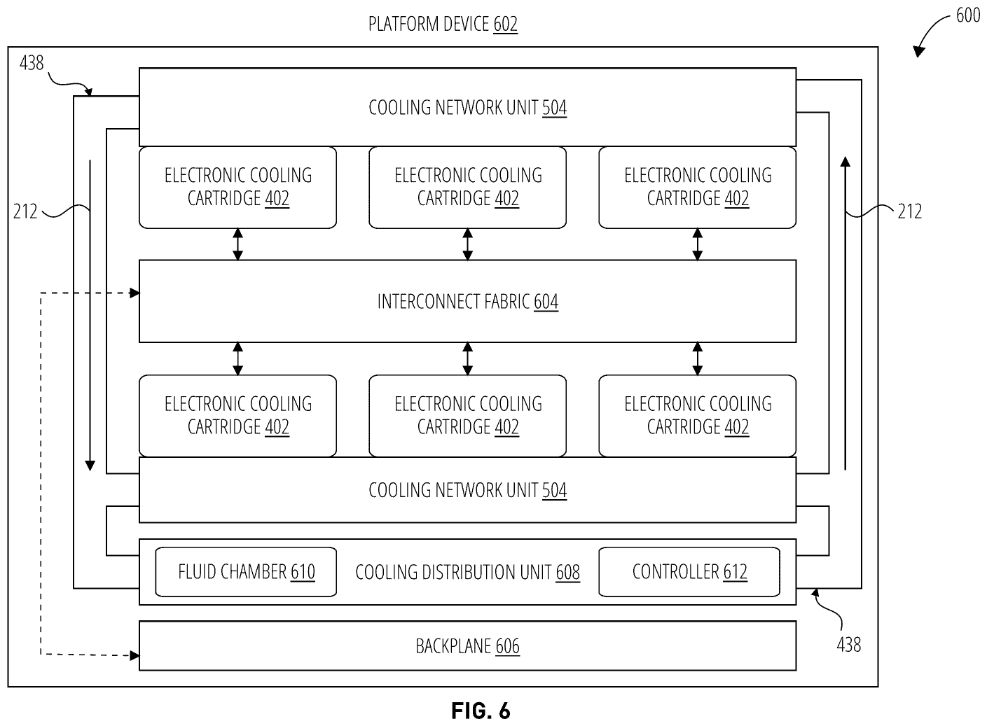

FIG. 6 illustrates a system 600 suitable for the semiconductor package 100, the apparatus 400, and the system 500. The system 600 comprises an example of a platform device 602 comprising a C number of electronic cooling cartridges 402 implemented as part of a larger platform or system, where C represents any positive integer.

As depicted in FIG. 6, the system 600 comprises a platform device 602 for a larger device, such as a server blade of a server system of a data center, for example. The platform device 602 comprises six electronic cooling cartridges 402 (C=6). The electronic cooling cartridges 402 interface with the cooling network units 504 using various cartridge bases 502 as described with reference to FIG. 5. The electronic cooling cartridges 402 also connect to an interconnect fabric 604 and a cooling distribution unit 608. The interconnect fabric 604 connects to a backplane 606.

The electronic cooling cartridges 402 connect to the interconnect fabric 604. The interconnect fabric 604 is a high-speed communication infrastructure that allows the electronic cooling cartridges 402 within the platform device 602 to communicate with each other and with external networks and devices. The interconnect fabric 604 enables data, control, and management traffic to flow between the electronic cooling cartridges 402 and also between the platform device 602 and a larger server system and other parts of a data center infrastructure via the backplane 606, such as a Peripheral Component Interconnect (PCIe) backplane 606, for example. The interconnect fabric 604 includes both hardware and software components. The hardware components includes the physical pathways for data transmission such as backplane connectors, cables, switches, and other networking hardware integrated within the platform device 602. These components are designed to provide high bandwidth and low latency connections. The software components encompass the protocols, interfaces, and management tools that facilitate communication over the hardware infrastructure. This software layer enables efficient data routing, security, and network configuration and troubleshooting. The design of the interconnect fabric 604 can vary based on a server model and the specific requirements of the data center, but its primary goal is to ensure robust, scalable, and flexible connectivity for all electronic cooling cartridges 402 within the platform device 602. This enables the electronic cooling cartridges 402 to operate cohesively as part of a larger computing resource, optimizing performance and reliability in processing, storage, and communication tasks.

The electronic cooling cartridges 402 connect to the cooling distribution unit 608 via one or more fluid pipes 438. The cooling distribution unit 608 in a liquid cooling system is a component designed to distribute the cooling fluid 210 stored in a fluid chamber 610 to multiple cooling points within the platform device 602. The cooling distribution unit 608 manages and maintains the efficiency of the cooling process. The cooling distribution unit 608 serves various functions. For example, the cooling distribution unit 608 performs a temperature regulation function. The cooling distribution unit 608 ensures that the cooling fluid 210 is at the correct temperature before it is circulated through the system. This involves cooling the liquid if it has warmed up after absorbing heat from the system components. The cooling distribution unit 608 performs a flow control function. It regulates the flow rate of the cooling fluid 210 to the various parts of the platform device 602 that require cooling, ensuring optimal heat exchange and system performance. The cooling distribution unit 608 can adjust the flow dynamically based on temperature readings and cooling demand from a set of sensors 408 internal to the electronic cooling cartridges 402 or implemented as part of the platform device 602. The cooling distribution unit 608 perform a pressure maintenance function. The cooling distribution unit 608 helps maintain the proper pressure within the cooling system, ensuring that the cooling fluid 210 circulates effectively without causing leaks or damage to the system components. The cooling distribution unit 608 performs a filtration function. The cooling distribution unit 608 may incorporate filters to remove particulates from the cooling fluid 210, thus preventing clogging and ensuring the longevity and efficiency of the cooling system. The cooling distribution unit 608 performs a deaeration function. The cooling distribution unit 608 may remove air bubbles from the cooling fluid 210. Air bubbles can reduce the effectiveness of heat transfer and lead to noise and vibration in the system. The cooling distribution unit 608 performs a coolant distribution function. The cooling distribution unit 608 directs the cooling fluid 210 to specific components or areas needing cooling, such as computer processors, power supplies, or electric vehicle battery packs, and then returns the warmed liquid back to the cooling system for re-cooling. The cooling distribution unit 608 is an important part of both small-scale and large-scale liquid cooling setups, including data center cooling systems, industrial process cooling, and cooling systems for high-performance computing and electronics. They contribute to system efficiency by ensuring that cooling resources are used optimally.

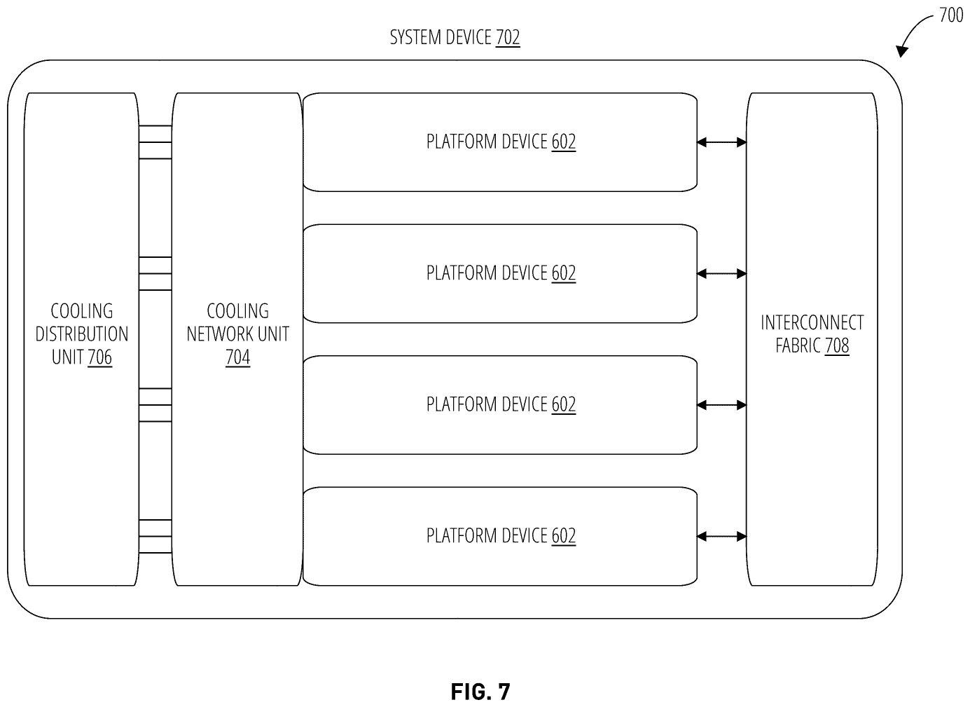

FIG. 7 illustrates a system 700. The system 700 comprises an example of a system device 702 comprising a P number of platform devices 602 implemented as part of a larger system, where P represents any positive integer.

As depicted in FIG. 7, the system 700 comprises a system device 702 for a larger system, such as a server rack or server system of a data center, for example. As shown, the system device 702 comprises four platform devices 602 (P=4). Each of the platform devices 602 interfaces with a cooling network unit 704, which is a system level version of the cooling network units 504 as described with reference to FIG. 5. The platform devices 602 also connect to an interconnect fabric 708, which is a system level version of the interconnect fabric 604, via the backplanes 606 of the platform devices 602. The platform devices 602 also connect to a cooling distribution unit 706, which is a system level version of the cooling distribution unit 608.

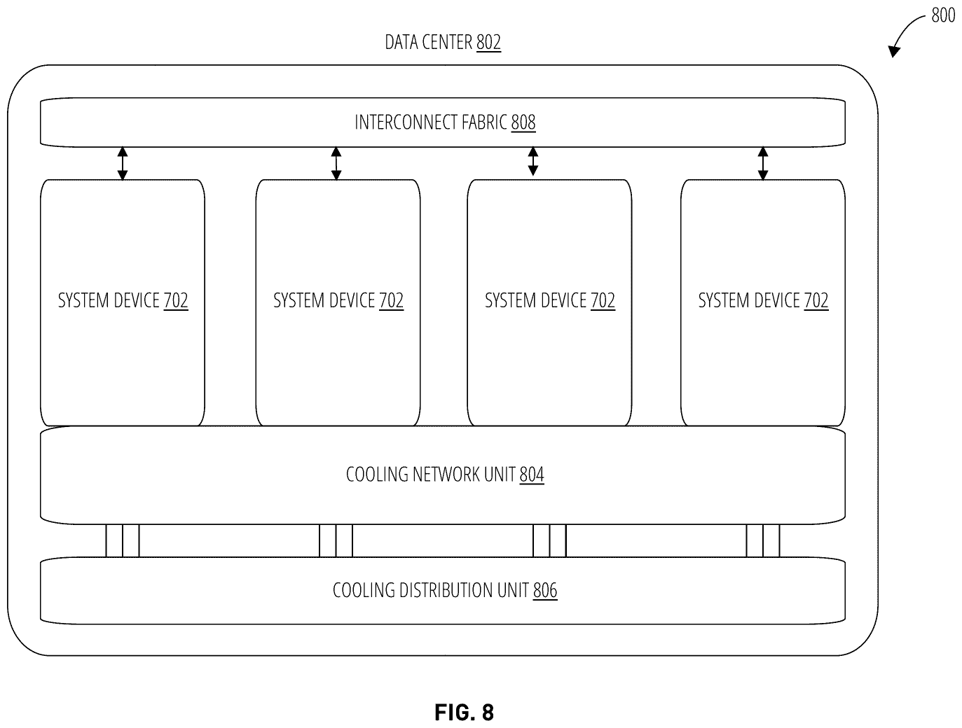

FIG. 8 illustrates a system 800. The system 800 comprises an example of a data center 802 comprising an S number of system devices 702 implemented as part of a larger system, where S represents any positive integer.

As depicted in FIG. 8, the system 800 comprises system devices 702 for a larger system, such as a data center 802, for example. As shown, the data center 802 comprises four system device 702 (S=4). Each of the system devices 702 interfaces with a cooling network unit 804, which is a data center level version of the cooling network units 504 as described with reference to FIG. 5. The system devices 702 also connect to an interconnect fabric 808, which is a data center level version of the interconnect fabric 604, via the interconnect fabric 708 of the system devices 702. The system devices 702 also connects to a cooling distribution unit 806, which is a data center level version of the cooling distribution unit 608 and/or cooling distribution unit 706.

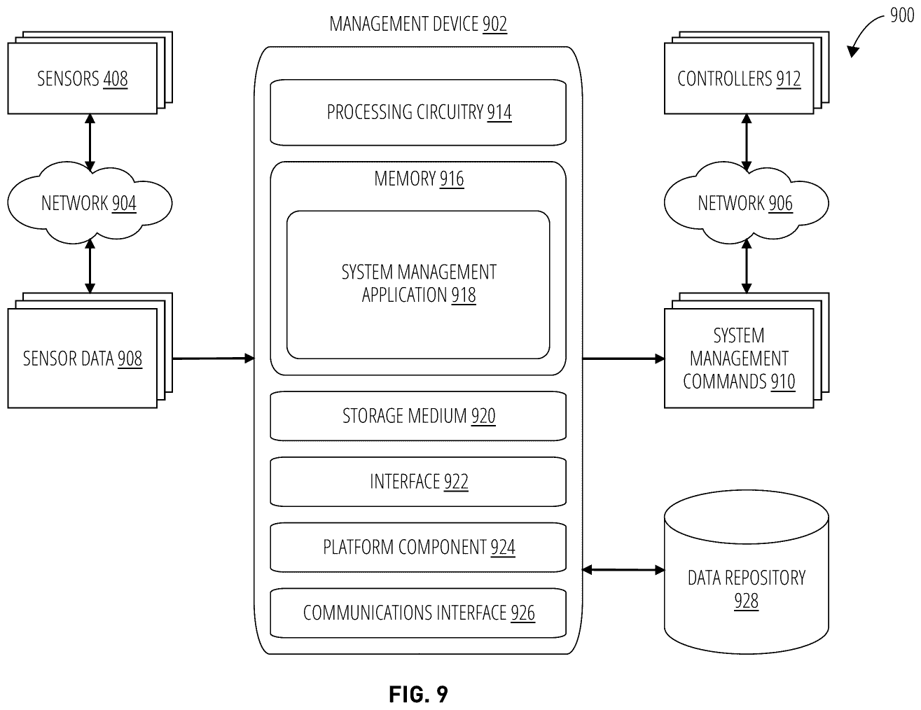

FIG. 9 illustrates an embodiment of a system 900. The system 900 is suitable for implementing one or more embodiments as described herein. In one embodiment, for example, the system 900 implements a management device 902 for receiving and decoding sensor data 908 from one or more sensors 408 of the apparatus 400, the system 500, the system 600, the system 700, and/or the system 800, analyzing the sensor data 908, and sending and encoding one or more system management commands 910 to the apparatus 400, the system 500, the system 600, the system 700, and/or the system 800.

The system 900 comprises a set of M devices, where M is any positive integer. FIG. 9 depicts three devices (M=3), including a set of sensors 408, a management device 902, and a set of controllers 912. The management device 902 communicates information with the sensors 408 and the controllers 912 over a network 904 and a network 906, respectively. The information may include sensor data 908 from the sensors 408 and system management commands 910 to the controllers 912.

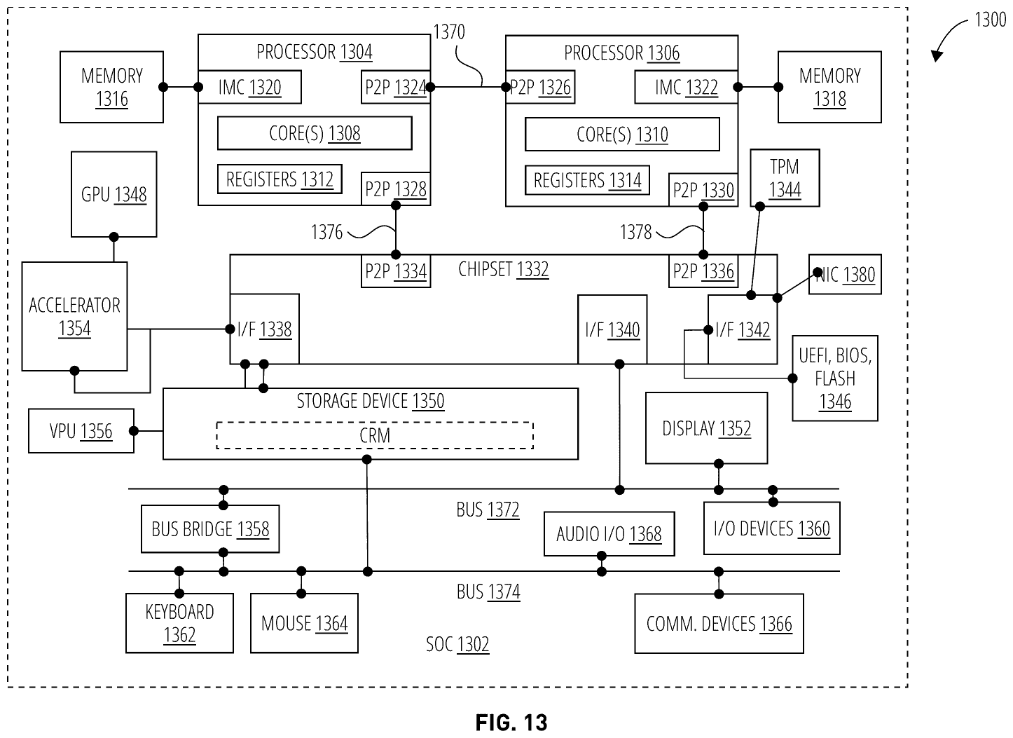

As depicted in FIG. 9, the management device 902 includes processing circuitry 914, a memory 916, a storage medium 920, an interface 922, and a platform component 924. In some implementations, the management device 902 includes other components or devices as well. Examples for software elements and hardware elements of the management device 902 are described in more detail with reference to a computing architecture 1300 as depicted in FIG. 13. Embodiments are not limited to these examples.

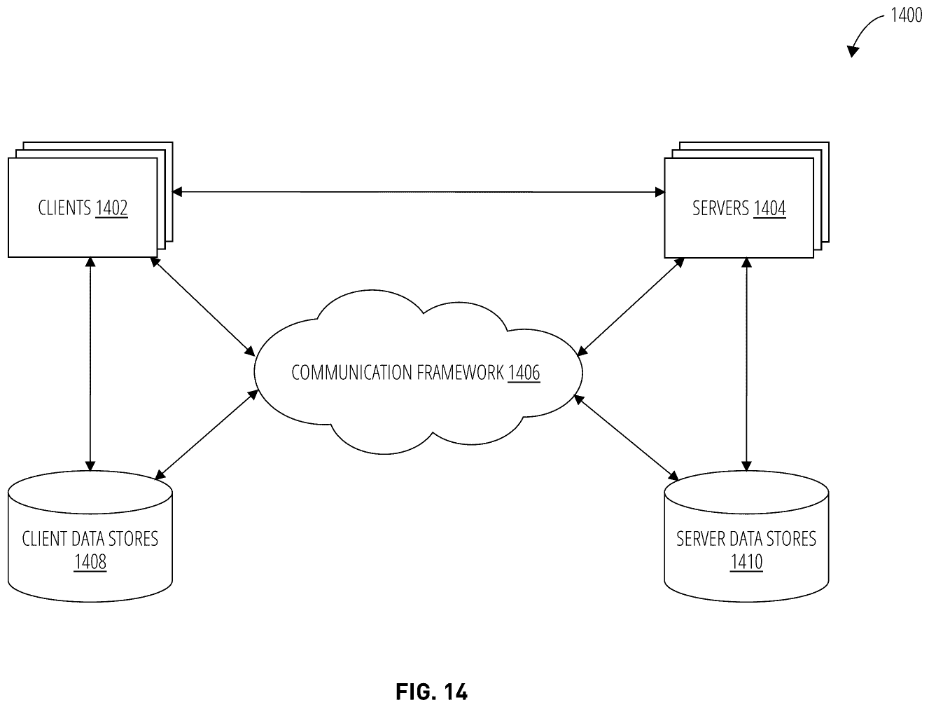

The management device 902 is generally arranged to receive sensor data 908, process the sensor data 908 via one or more analysis techniques, and send system management commands 910. The management device 902 receives the sensor data 908 from the sensors 408 via the network 904. The management device 902 sends the system management commands 910 to the controllers 912 via the network 906, the platform component 924 (e.g., a touchscreen as a text command or microphone as a voice command), the system management application 918, the memory 916, the storage medium 920, or the data repository 928. Examples for the software elements and hardware elements of the network 904 and the network 906 are described in more detail with reference to a communications architecture 1400 as depicted in FIG. 14. Embodiments are not limited to these examples.

In one embodiment, the controllers 912 control various internal electronic components and/or internal cooling components of the electronic cooling cartridge 402. For example, the fluid distribution unit 426 and/or the fluid collection unit 428 may be controlled by system management commands 910 received from the system management application 918 via a management connector for the electronic cooling cartridge 402. For instance, a system operator or an automated system may use the system management application 918 to generate command and control directives for the liquid cooling system of the electronic cooling cartridge 402 in response to measurements received from the one or more sensors 408. Examples of system management commands 910 include a set of control directives, such as a control directive to the fluid distribution unit 426 to release the cooling fluid 210 from the fluid ingress port 422 into the fluid pipes 438, a control directive to the fluid collection unit 428 to drain the cooling fluid 210 from the fluid pipes 438 to the fluid egress port 424, a control directive to control types of the cooling fluid 210 to release into the fluid pipes 438 or drain from the fluid pipe 438, a control directive to control an amount of the cooling fluid 210 to release into the fluid pipe 438 or draft from the fluid pipe 438, and other management operations for the cooling components of the electronic cooling cartridge 402.

In one embodiment, for example, the system management application 918 may instruct the electronic cooling cartridge 402 to use different cooling techniques, such as a hybrid cooling technique combining the use of cold plates and different types of cooling fluids depending on thermal design power (TDP) requirements and environmental conditions supporting different climate conditions. For instance, a data center located in colder climates would require less cooling relative to a data center located in warmer climates that require more cooling. Further, some locations may shift between a colder climate and a warmer climate on a seasonal basis, thereby necessitating different electronic cooling modules with different cooling liquids during different seasons in a given year. To service an electronic cooling cartridge housing the semiconductor dies 104, such as an XPU, the XPU is powered down, the cooling fluid 210 is pumped out of the fluid pipes 438 and/or the closed container 404, and it is ready for safe removal from the platform device 602 or the system device 702. For reinsertion, a system operator can insert the electronic cooling cartridge 402 with the empty closed container 404 into the platform device 602 or the system device 702, access the system management application 918 to select a cooling fluid 210 for the empty closed container 404. A fluid pump from a cooling distribution unit, such as the cooling distribution unit 506, the cooling distribution unit 608, cooling distribution unit 706, or the cooling distribution unit 806, moves the liquid into the internal cooling components of the electronic cooling cartridge 402, and the system powers on the XPU to become operational once again. Embodiments are not limited to these examples.

Operations for the disclosed embodiments are further described with reference to the following figures. Some of the figures include a logic flow. Although such figures presented herein include a particular logic flow, the logic flow merely provides an example of how the general functionality as described herein is implemented. Further, a given logic flow does not necessarily have to be executed in the order presented unless otherwise indicated. Moreover, not all acts illustrated in a logic flow are required in some embodiments. In addition, the given logic flow is implemented by a hardware element, a software element executed by one or more processing devices, or any combination thereof. The embodiments are not limited in this context.

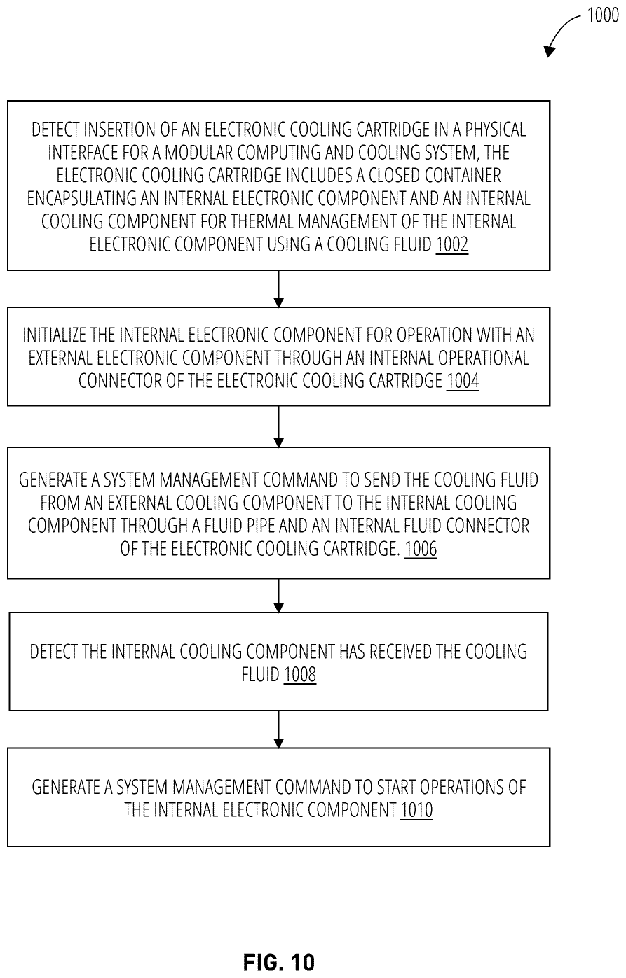

FIG. 10 illustrates an embodiment of a logic flow 1000. The logic flow 1000 is representative of some or all of the operations executed by one or more embodiments described herein. For example, the logic flow 1000 includes some or all of the operations performed by devices or entities within the semiconductor package 100, semiconductor device 200, the modular computing and cooling system 300, apparatus 400, system 500, system 600, system 700, system 800, or system 900. In one embodiment, the logic flow 1000 is implemented as instructions stored on a non-transitory computer-readable storage medium, such as the storage medium 920, that when executed by the processing circuitry 914 causes the processing circuitry 914 to perform the described operations. The storage medium 920 and processing circuitry 914 may be co-located, or the instructions may be stored remotely from the processing circuitry 914. Collectively, the storage medium 920 and the processing circuitry 914 may form a system.

In block 1002, the logic flow 1000 comprises detecting insertion of an electronic cooling cartridge in a physical interface for a modular computing and cooling system, the electronic cooling cartridge includes a closed container encapsulating an internal electronic component and an internal cooling component for thermal management of the internal electronic component using a cooling fluid. In block 1004, the logic flow 1000 comprises initializing the internal electronic component for operation with an external electronic component through an internal operational connector of the electronic cooling cartridge. In block 1006, the logic flow 1000 comprises generating a system management command to send the cooling fluid from an external cooling component to the internal cooling component through a fluid pipe and an internal fluid connector of the electronic cooling cartridge. In block 1008, the logic flow 1000 comprises detecting the internal cooling component has received the cooling fluid. In block 1010, the logic flow 1000 comprises generating a system management command to start operations of the internal electronic component.

By way of example, the system management application 918 detects insertion of an electronic cooling cartridge 302 in a physical interface 306 for a modular computing and cooling system 300. The electronic cooling cartridge 302 includes a closed container 314 encapsulating one or more internal electronic components 308 and one or more internal cooling components 310 for thermal management of the internal electronic components 308 using a cooling fluid 210. The system management application 918 initializes the one or more internal electronic components 308 for operation with one or more external electronic components 318 through an internal operational connector 412 of the electronic cooling cartridge 302. The system management application 918 generates one or more of the system management commands 910 to send the cooling fluid 210 from one or more external cooling components 320 to the one or more internal cooling components 310 through a fluid pipe 328 and an internal fluid connector, such as fluid ingress port 422 of the electronic cooling cartridge 302. The system management application 918 detects the one or more internal cooling components 310 have received the cooling fluid 210. The system management application 918 generates a system management command to start operations of the one or more internal electronic components 308.

In one embodiment, for example, the system management application 918 receives sensor measurements for the one or more internal cooling components 310 from sensors 408. The system management application 918 analyzes the sensor measurements to determine whether adjustments are needed for the cooling fluid 210 of the one or more internal cooling components 310 based on the sensor measurements. The system management application 918 generates one or more system management commands 910 to adjust the cooling fluid 210 for the one or more internal cooling components 310 in accordance with the determination. For example, the system management application 918 may determine to adjust an amount of the cooling fluid 210 needed for the one or more internal cooling components 310, such as adding more cooling fluid 210 or removing some of the cooling fluid 210.

In one embodiment, for example, the system management application 918 may determine to adjust a type of cooling fluid 210 needed for one or more internal cooling components 310. In a liquid cooling system, the choice of cooling fluid is important for system efficiency, effectiveness, and longevity. Various types of cooling fluids are used based on their thermal conductivity, specific heat capacity, viscosity, and chemical stability. Non-limiting examples of different types of cooling fluids include: (1) pure distilled water is often used due to its high thermal conductivity and specific heat capacity, making it effective at absorbing and transferring heat; (2) antifreeze solutions such as Ethylene glycol or propylene glycol mixed with water can lower the freezing point and raise the boiling point of the cooling mixture, making the system more efficient in extreme temperatures, while also inhibiting corrosion and biological growth; (3) dielectric fluids which are electrically non-conductive fluids used in systems where there is a risk of electrical components coming into contact with the liquid, such as fluorocarbons and synthetic oils, which are especially useful in direct immersion cooling systems for electronics; (4) mineral oils and synthetic oils are sometimes used for their dielectric properties and high boiling points useful in applications requiring electrical insulation or where leakages could pose a risk to electrical components; (5) nanofluids which are engineered fluids created by dispersing nanometer-sized particles (such as metallic oxides) in a base fluid like water or glycol mixtures, where the nanoparticles can significantly enhance the thermal conductivity of the fluid; (6) refrigerants for systems where phase change cooling is used (similar to air conditioners), such as refrigerants like R134a or newer environmentally friendly alternatives are used, which absorb heat by evaporating at low temperatures and release heat upon condensation; (7) corrosion inhibitors and biocides when using water or water-glycol solutions to help protect the cooling system components and extend the fluid usable life. The choice among these fluids depends on the application's specific requirements, including thermal performance, electrical insulation, compatibility with system materials, and environmental considerations.

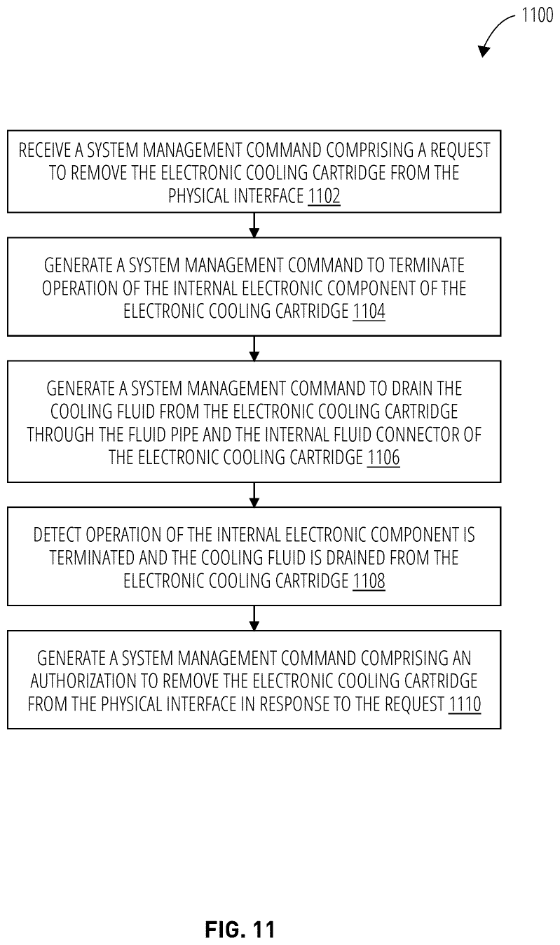

FIG. 11 illustrates an embodiment of a logic flow 1100. The logic flow 1100 is representative of some or all of the operations executed by one or more embodiments described herein. For example, the logic flow 1100 includes some or all of the operations performed by devices or entities within the semiconductor package 100, semiconductor device 200, the modular computing and cooling system 300, apparatus 400, system 500, system 600, system 700, system 800, or system 900. In one embodiment, the logic flow 1100 is implemented as instructions stored on a non-transitory computer-readable storage medium, such as the storage medium 920, that when executed by the processing circuitry 914 causes the processing circuitry 914 to perform the described operations. The storage medium 920 and processing circuitry 914 may be co-located, or the instructions may be stored remotely from the processing circuitry 914. Collectively, the storage medium 920 and the processing circuitry 914 may form a system.

In block 1102, the logic flow 1100 comprises receiving a system management command includes a request to remove the electronic cooling cartridge from the physical interface. In block 1104, the logic flow 1100 comprises generating a system management command to terminate operation of the internal electronic component of the electronic cooling cartridge. In block 1106, the logic flow 1100 comprises generating a system management command to drain the cooling fluid from the electronic cooling cartridge through the fluid pipe and the internal fluid connector of the electronic cooling cartridge. In block 1108, the logic flow 1100 comprises detecting operation of the internal electronic component is terminated and the cooling fluid is drained from the electronic cooling cartridge. In block 1110, the logic flow 1100 comprises generating a system management command includes an authorization to remove the electronic cooling cartridge from the physical interface in response to the request.

By way of example, the system management application 918 receives one or more system management commands 910 comprising a request to remove the electronic cooling cartridge 302 from the physical interface 306. The system management application 918 generates one or more system management commands 910 to terminate operation of the one or more internal electronic components 308 of the electronic cooling cartridge 302. The system management application 918 generates one or more system management commands 910 to drain the cooling fluid 210 from the electronic cooling cartridge 302 through the fluid pipe 328 and the internal fluid connector, such as fluid egress port 424 of the electronic cooling cartridge 302. The system management application 918 detects operation of the one or more internal electronic components 308 are terminated and the cooling fluid 210 is drained from the electronic cooling cartridge 302. The system management application 918 generates one or more system management commands 910 comprising an authorization to remove the electronic cooling cartridge 302 from the physical interface 306 in response to the request.

In one embodiment, for example, the system management application 918 generates an authorization signal representing the authorization to remove the electronic cooling cartridge 302 from the physical interface 306. The system management application 918 then generates an audible, visual or vibratory signal to notify a system operator that it is safe to remove the electronic cooling cartridge 302 from the physical interface 306. For example, the system management application 918 causes display of a message by a user interface on an electronic display for the electronic cooling cartridge 302, either an electronic display of a system management computer or an electronic display mounted on the outside of the closed container 314 of the electronic cooling cartridge 302. Additionally or alternatively, the system management application 918 may cause activation of a semiconductor device mounted on the closed container 314, such as a light emitting diode (LED) or some other visual indicator. Additionally or alternatively, the system management application 918 causes an electronic locking mechanism to physically unlock the electronic cooling cartridge 302 from the physical interface 306.

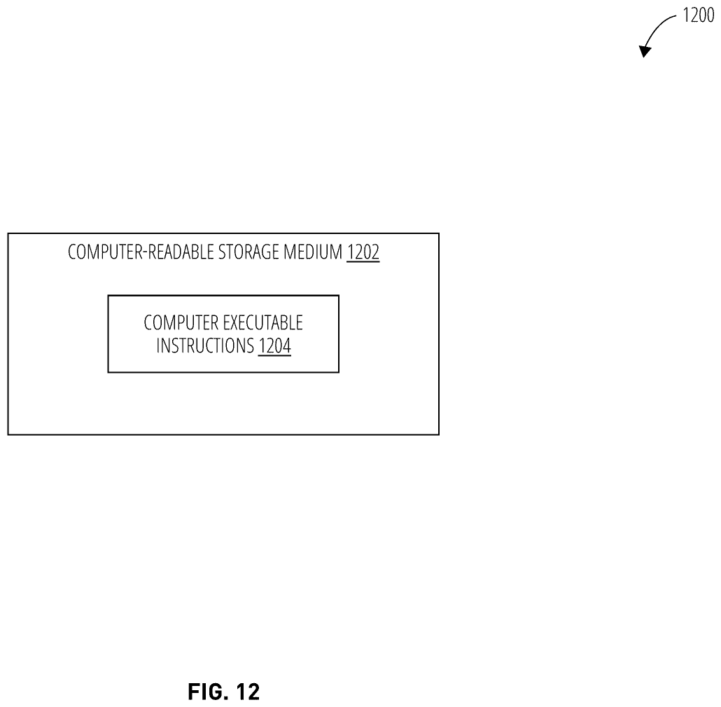

FIG. 12 illustrates an apparatus 1200. Apparatus 1200 comprises any non-transitory computer-readable storage medium 1202 or machine-readable storage medium, such as an optical, magnetic or semiconductor storage medium. In various embodiments, apparatus 1200 comprises an article of manufacture or a product. In some embodiments, the computer-readable storage medium 1202 stores computer executable instructions with which one or more processing devices or processing circuitry can execute. For example, computer executable instructions 1204 includes instructions to implement operations described with respect to any logic flows described herein. Examples of computer-readable storage medium 1202 or machine-readable storage medium include any tangible media capable of storing electronic data, including volatile memory or non-volatile memory, removable or non-removable memory, erasable or non-erasable memory, writeable or re-writeable memory, and so forth. Examples of computer executable instructions 1204 include any suitable type of code, such as source code, compiled code, interpreted code, executable code, static code, dynamic code, object-oriented code, visual code, and the like.

FIG. 13 illustrates an embodiment of a computing architecture 1300. Computing architecture 1300 is a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the computing architecture 1300 has a single processor with one core or more than one processor. Note that the term “processor” refers to a processor with a single core or a processor package with multiple processor cores. In at least one embodiment, the computing architecture 1300 is representative of the components of the system 900. More generally, the computing architecture 1300 is configured to implement all logic, systems, logic flows, methods, apparatuses, and functionality described herein with reference to previous figures.

As used in this application, the terms “system” and “component” and “module” are intended to refer to a computer-related entity, either hardware, a combination of hardware and software, software, or software in execution, examples of which are provided by the exemplary computing architecture 1300. For example, a component is, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server are a component. One or more components reside within a process and/or thread of execution, and a component is localized on one computer and/or distributed between two or more computers. Further, components are communicatively coupled to each other by various types of communications media to coordinate operations. The coordination involves the uni-directional or bi-directional exchange of information. For instance, the components communicate information in the form of signals communicated over the communications media. The information is implemented as signals allocated to various signal lines. In such allocations, each message is a signal. Further embodiments, however, alternatively employ data messages. Such data messages may be sent across various connections. Exemplary connections include parallel interfaces, serial interfaces, and bus interfaces.

As shown in FIG. 13, computing architecture 1300 comprises a system-on-chip (SoC) 1302 for mounting platform components. System-on-chip (SoC) 1302 is a point-to-point (P2P) interconnect platform that includes a first processor 1304 and a second processor 1306 coupled via a point-to-point interconnect 1370 such as an Ultra Path Interconnect (UPI). In other embodiments, the computing architecture 1300 is another bus architecture, such as a multi-drop bus. Furthermore, each of processor 1304 and processor 1306 are processor packages with multiple processor cores including core(s) 1308 and core(s) 1310, respectively. While the computing architecture 1300 is an example of a two-socket (2S) platform, other embodiments include more than two sockets or one socket. For example, some embodiments include a four-socket (4S) platform or an eight-socket (8S) platform. Each socket is a mount for a processor and may have a socket identifier. Note that the term platform refers to a motherboard with certain components mounted such as the processor 1304 and chipset 1332. Some platforms include additional components and some platforms include sockets to mount the processors and/or the chipset. Furthermore, some platforms do not have sockets (e.g. SoC, or the like). Although depicted as a SoC 1302, one or more of the components of the SoC 1302 are included in a single die package, a multi-chip module (MCM), a multi-die package, a chiplet, a bridge, and/or an interposer. Therefore, embodiments are not limited to a SoC.

The processor 1304 and processor 1306 are any commercially available processors, including without limitation an Intel® Celeron®, Core®, Core (2) Duo®, Itanium®, Pentium®, Xcon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures are also employed as the processor 1304 and/or processor 1306. Additionally, the processor 1304 need not be identical to processor 1306.

Processor 1304 includes an integrated memory controller (IMC) 1320 and point-to-point (P2P) interface 1324 and P2P interface 1328. Similarly, the processor 1306 includes an IMC 1322 as well as P2P interface 1326 and P2P interface 1330. IMC 1320 and IMC 1322 couple the processor 1304 and processor 1306, respectively, to respective memories (e.g., memory 1316 and memory 1318). Memory 1316 and memory 1318 are portions of the main memory (e.g., a dynamic random-access memory (DRAM)) for the platform such as double data rate type 4 (DDR4) or type 5 (DDR5) synchronous DRAM (SDRAM). In the present embodiment, the memory 1316 and the memory 1318 locally attach to the respective processors (i.e., processor 1304 and processor 1306). In other embodiments, the main memory couple with the processors via a bus and shared memory hub. Processor 1304 includes registers 1312 and processor 1306 includes registers 1314.

Computing architecture 1300 includes chipset 1332 coupled to processor 1304 and processor 1306. Furthermore, chipset 1332 are coupled to storage device 1350, for example, via an interface (I/F) 1338. The I/F 1338 may be, for example, a Peripheral Component Interconnect-enhanced (PCIe) interface, a Compute Express Link® (CXL) interface, or a Universal Chiplet Interconnect Express (UCIe) interface. Storage device 1350 stores instructions executable by circuitry of computing architecture 1300 (e.g., processor 1304, processor 1306, GPU 1348, accelerator 1354, vision processing unit 1356, or the like). For example, storage device 1350 can store instructions for the client device 802, the client device 804, the management device 902, the training device 714, or the like.

Processor 1304 couples to the chipset 1332 via P2P interface 1328 and P2P 1334 while processor 1306 couples to the chipset 1332 via P2P interface 1330 and P2P 1336. Direct media interface (DMI) 1376 and DMI 1378 couple the P2P interface 1328 and the P2P 1334 and the P2P interface 1330 and P2P 1336, respectively. DMI 1376 and DMI 1378 is a high-speed interconnect that facilitates, e.g., eight Giga Transfers per second (GT/s) such as DMI 3.0. In other embodiments, the processor 1304 and processor 1306 interconnect via a bus.

The chipset 1332 comprises a controller hub such as a platform controller hub (PCH). The chipset 1332 includes a system clock to perform clocking functions and include interfaces for an I/O bus such as a universal serial bus (USB), peripheral component interconnects (PCIs), CXL interconnects, UCIe interconnects, interface serial peripheral interconnects (SPIs), integrated interconnects (I2Cs), and the like, to facilitate connection of peripheral devices on the platform. In other embodiments, the chipset 1332 comprises more than one controller hub such as a chipset with a memory controller hub, a graphics controller hub, and an input/output (I/O) controller hub.

In the depicted example, chipset 1332 couples with a trusted platform module (TPM) 1344 and UEFI, BIOS, FLASH circuitry 1346 via I/F 1342. The TPM 1344 is a dedicated microcontroller designed to secure hardware by integrating cryptographic keys into devices. The UEFI, BIOS, FLASH circuitry 1346 may provide pre-boot code. The I/F 1342 may also be coupled to a network interface circuit (NIC) 1380 for connections off-chip.

Furthermore, chipset 1332 includes the I/F 1338 to couple chipset 1332 with a high-performance graphics engine, such as, graphics processing circuitry or a graphics processing unit (GPU) 1348. In other embodiments, the computing architecture 1300 includes a flexible display interface (FDI) (not shown) between the processor 1304 and/or the processor 1306 and the chipset 1332. The FDI interconnects a graphics processor core in one or more of processor 1304 and/or processor 1306 with the chipset 1332.

The computing architecture 1300 is operable to communicate with wired and wireless devices or entities via the network interface (NIC) 180 using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, 3G, 4G, LTE wireless technologies, among others. Thus, the communication is a predefined structure as with a conventional network or simply an ad hoc communication between at least two devices. Wi-Fi networks use radio technologies called IEEE 802.11x (a, b, g, n, ac, ax, etc.) to provide secure, reliable, fast wireless connectivity. A Wi-Fi network is used to connect computers to each other, to the Internet, and to wired networks (which use IEEE 802.3-related media and functions).

Additionally, accelerator 1354 and/or vision processing unit 1356 are coupled to chipset 1332 via I/F 1338. The accelerator 1354 is representative of any type of accelerator device (e.g., a data streaming accelerator, cryptographic accelerator, cryptographic co-processor, an offload engine, etc.). One example of an accelerator 1354 is the Intel® Data Streaming Accelerator (DSA). The accelerator 1354 is a device including circuitry to accelerate copy operations, data encryption, hash value computation, data comparison operations (including comparison of data in memory 1316 and/or memory 1318), and/or data compression. Examples for the accelerator 1354 include a USB device, PCI device, PCIe device, CXL device, UCIe device, and/or an SPI device. The accelerator 1354 also includes circuitry arranged to execute machine learning (ML) related operations (e.g., training, inference, etc.) for ML models. Generally, the accelerator 1354 is specially designed to perform computationally intensive operations, such as hash value computations, comparison operations, cryptographic operations, and/or compression operations, in a manner that is more efficient than when performed by the processor 1304 or processor 1306. Because the load of the computing architecture 1300 includes hash value computations, comparison operations, cryptographic operations, and/or compression operations, the accelerator 1354 greatly increases performance of the computing architecture 1300 for these operations.

The accelerator 1354 includes one or more dedicated work queues and one or more shared work queues (each not pictured). Generally, a shared work queue is configured to store descriptors submitted by multiple software entities. The software is any type of executable code, such as a process, a thread, an application, a virtual machine, a container, a microservice, etc., that share the accelerator 1354. For example, the accelerator 1354 is shared according to the Single Root I/O virtualization (SR-IOV) architecture and/or the Scalable I/O virtualization (S-IOV) architecture. Embodiments are not limited in these contexts. In some embodiments, software uses an instruction to atomically submit the descriptor to the accelerator 1354 via a non-posted write (e.g., a deferred memory write (DMWr)). One example of an instruction that atomically submits a work descriptor to the shared work queue of the accelerator 1354 is the ENQCMD command or instruction (which may be referred to as “ENQCMD” herein) supported by the Intel® Instruction Set Architecture (ISA). However, any instruction having a descriptor that includes indications of the operation to be performed, a source virtual address for the descriptor, a destination virtual address for a device-specific register of the shared work queue, virtual addresses of parameters, a virtual address of a completion record, and an identifier of an address space of the submitting process is representative of an instruction that atomically submits a work descriptor to the shared work queue of the accelerator 1354. The dedicated work queue may accept job submissions via commands such as the movdir64b instruction.

Various I/O devices 1360 and display 1352 couple to the bus 1372, along with a bus bridge 1358 which couples the bus 1372 to a second bus 1374 and an I/F 1340 that connects the bus 1372 with the chipset 1332. In one embodiment, the second bus 1374 is a low pin count (LPC) bus. Various input/output (I/O) devices couple to the second bus 1374 including, for example, a keyboard 1362, a mouse 1364 and communication devices 1366.

Furthermore, an audio I/O 1368 couples to second bus 1374. Many of the I/O devices 1360 and communication devices 1366 reside on the system-on-chip (SoC) 1302 while the keyboard 1362 and the mouse 1364 are add-on peripherals. In other embodiments, some or all the I/O devices 1360 and communication devices 1366 are add-on peripherals and do not reside on the system-on-chip (SoC) 1302.

FIG. 14 illustrates a block diagram of an exemplary communications architecture 1400 suitable for implementing various embodiments as previously described. The communications architecture 1400 includes various common communications elements, such as a transmitter, receiver, transceiver, radio, network interface, baseband processor, antenna, amplifiers, filters, power supplies, and so forth. The embodiments, however, are not limited to implementation by the communications architecture 1400.

As shown in FIG. 14, the communications architecture 1400 includes one or more clients 1402 and servers 1404. The clients 1402 and the servers 1404 are operatively connected to one or more respective client data stores 1408 and server data stores 1410 that can be employed to store information local to the respective clients 1402 and servers 1404, such as cookies and/or associated contextual information.

The clients 1402 and the servers 1404 communicate information between each other using a communication framework 1406. The communication framework 1406 implements any well-known communications techniques and protocols. The communication framework 1406 is implemented as a packet-switched network (e.g., public networks such as the Internet, private networks such as an enterprise intranet, and so forth), a circuit-switched network (e.g., the public switched telephone network), or a combination of a packet-switched network and a circuit-switched network (with suitable gateways and translators).

The communication framework 1406 implements various network interfaces arranged to accept, communicate, and connect to a communications network. A network interface is regarded as a specialized form of an input output interface. Network interfaces employ connection protocols including without limitation direct connect, Ethernet (e.g., thick, thin, twisted pair 10/900/1000 Base T, and the like), token ring, wireless network interfaces, cellular network interfaces, IEEE 802.11 network interfaces, IEEE 802.16 network interfaces, IEEE 802.20 network interfaces, and the like. Further, multiple network interfaces are used to engage with various communications network types. For example, multiple network interfaces are employed to allow for the communication over broadcast, multicast, and unicast networks. Should processing requirements dictate a greater amount speed and capacity, distributed network controller architectures are similarly employed to pool, load balance, and otherwise increase the communicative bandwidth required by clients 1402 and the servers 1404. A communications network is any one and the combination of wired and/or wireless networks including without limitation a direct interconnection, a secured custom connection, a private network (e.g., an enterprise intranet), a public network (e.g., the Internet), a Personal Area Network (PAN), a Local Area Network (LAN), a Metropolitan Area Network (MAN), an Operating Missions as Nodes on the Internet (OMNI), a Wide Area Network (WAN), a wireless network, a cellular network, and other communications networks.

The various elements of the devices as previously described with reference to the figures include various hardware elements, software elements, or a combination of both. Examples of hardware elements include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements varies in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment are implemented by representative instructions stored on a machine-readable medium which represents various logic within the processor, which when read by a machine causes the machine to fabricate logic to perform the techniques described herein. Such representations, known as “intellectual property (IP) cores” are stored on a tangible, machine readable medium and supplied to various customers or manufacturing facilities to load into the fabrication machines that make the logic or processor. Some embodiments are implemented, for example, using a machine-readable medium or article which may store an instruction or a set of instructions that, when executed by a machine, causes the machine to perform a method and/or operations in accordance with the embodiments. Such a machine includes, for example, any suitable processing platform, computing platform, computing device, processing device, computing system, processing system, processing devices, computer, processor, or the like, and is implemented using any suitable combination of hardware and/or software. The machine-readable medium or article includes, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions include any suitable type of code, such as source code, compiled code, interpreted code, executable code, static code, dynamic code, encrypted code, and the like, implemented using any suitable high-level, low-level, object-oriented, visual, compiled and/or interpreted programming language.

As utilized herein, terms “component,” “system,” “interface,” and the like are intended to refer to a computer-related entity, hardware, software (e.g., in execution), and/or firmware. For example, a component is a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server is also a component. One or more components reside within a process, and a component is localized on one computer and/or distributed between two or more computers. A set of elements or a set of other components are described herein, in which the term “set” can be interpreted as “one or more.”

Further, these components execute from various computer readable storage media having various data structures stored thereon such as with a module, for example. The components communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component is an apparatus with specific functionality provided by mechanical parts operated by electric or electronic circuitry, in which the electric or electronic circuitry is operated by a software application or a firmware application executed by one or more processors. The one or more processors are internal or external to the apparatus and execute at least a part of the software or firmware application. As yet another example, a component is an apparatus that provides specific functionality through electronic components without mechanical parts; the electronic components include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry is implemented in, or functions associated with the circuitry are implemented by, one or more software or firmware modules. In some embodiments, circuitry includes logic, at least partially operable in hardware. It is noted that hardware, firmware and/or software elements may be collectively or individually referred to herein as “logic” or “circuit.”

Some embodiments are described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately can be employed in combination with each other unless it is noted that the features are incompatible with each other.

Some embodiments are presented in terms of program procedures executed on a computer or network of computers. A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments are described using the expression “coupled” and “connected” along with their derivatives. These terms are not necessarily intended as synonyms for each other. For example, some embodiments are described using the terms “connected” and/or “coupled” to indicate that two or more elements are in direct physical or electrical contact with each other. The term “coupled,” however, also means that two or more elements are not in direct contact with each other, but yet still co-operate or interact with each other.

Various embodiments also relate to apparatus or systems for performing these operations. This apparatus is specially constructed for the required purpose or it comprises a general purpose computer as selectively activated or reconfigured by a computer program stored in the computer. The procedures presented herein are not inherently related to a particular computer or other apparatus. Various general purpose machines are used with programs written in accordance with the teachings herein, or it proves convenient to construct more specialized apparatus to perform the required method steps. The required structure for a variety of these machines are apparent from the description given.

It is emphasized that the Abstract of the Disclosure is provided to allow a reader to quickly ascertain the nature of the technical disclosure. It is submitted with the understanding that it will not be used to interpret or limit the scope or meaning of the claims. In addition, the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The following examples pertain to further embodiments, from which numerous permutations and configurations will be apparent.

In one example, an apparatus, includes a physical interface for a modular computing and cooling system. The apparatus also includes an electronic cooling cartridge for insertion into the physical interface and removal from the physical interface, the electronic cooling cartridge includes an internal electronic component, an internal cooling component for thermal management of the internal electronic component using a cooling fluid, a set of internal connectors to connect the internal electronic component and the internal cooling component to an external electronic component and an external cooling component, respectively, of the modular computing and cooling system, and a closed container encapsulating the internal electronic component, the internal cooling component, and the set of internal connectors.

The apparatus may also include the physical interface to physically connect the electronic cooling cartridge to a computing and cooling system includes a chassis housing the external electronic component and the external cooling component.

The apparatus may also include the internal electronic component includes a semiconductor die mounted on a substrate.

The apparatus may also include the internal cooling component includes a cooling unit for a semiconductor die, the cooling unit includes a liquid cooling component of a liquid cooling system.

The apparatus may also include the internal cooling component includes a cooling unit, a fluid distribution unit, and a fluid pipe to connect the cooling unit and the fluid distribution unit, the fluid distribution unit to receive the cooling fluid from a fluid ingress port of the set of connectors and distribute the cooling fluid through the fluid pipe to the cooling unit for thermal management of the semiconductor die using the cooling fluid.

The apparatus may also include the internal cooling component includes a cooling unit, a fluid distribution unit, a fluid collection unit, and a set of fluid pipes to connect the cooling unit, the fluid distribution unit, and the fluid collection unit, the fluid distribution unit to receive the cooling fluid from a fluid ingress port of the set of connectors and distribute the cooling fluid through a fluid pipe to the cooling unit for thermal management of the semiconductor die using the cooling fluid, and the fluid collection unit to collect heated cooling fluid through a fluid pipe from the cooling unit, and send the heating cooling fluid to a fluid egress port of the set of connectors.

The apparatus may also include a sensor to measure a physical characteristic of the electronic cooling cartridge.

The apparatus may also include a controller electrically or optically coupled to the internal cooling component, the controller to instruct the internal cooling component to remove cooling fluid from the electronic cooling cartridge to allow removal of the electronic cooling cartridge from the physical interface, or the controller to instruct the internal cooling component to add cooling fluid to the electronic cooling cartridge after insertion of the electronic cooling cartridge into the physical interface.

The apparatus may also include the physical interface includes a cartridge base to physically connect the electronic cooling cartridge and a cooling network unit of the modular computing and cooling system.

In one example, a system, includes a platform device for a modular computing and cooling system, the platform device includes an interconnect fabric to communicate control and data signals. The system also includes a platform device for a modular computing and cooling system, the platform device includes a cooling distribution unit to distribute cooling fluid. The system also includes a platform device for a modular computing and cooling system, the platform device includes a cooling network unit connected to the cooling distribution unit by a fluid pipe, the cooling network unit includes a physical interface to the cooling distribution unit; a set of electronic cooling cartridges for insertion into the cooling network unit and removal from the cooling network unit, an electronic cooling cartridge from the set of electronic cooling cartridges includes an internal electronic component, an internal cooling component for thermal management of the internal electronic component using the cooling fluid from the cooling distribution unit, a set of internal connectors to connect the internal electronic component to the interconnect fabric and the internal cooling component to the cooling distribution unit, and a closed container encapsulating the internal electronic component, the internal cooling component, and the set of internal connectors.

The system may also include the cooling network unit to physically connect the set of electronic cooling cartridges to a computing and cooling system includes a chassis housing the interconnect fabric, the cooling distribution unit, and the cooling network unit. The system may also include the internal electronic component includes a semiconductor die mounted on a substrate.

The system may also include the internal cooling component includes a cooling unit for a semiconductor die, the cooling unit includes a liquid cooling component of a liquid cooling system.

The system may also include the internal cooling component includes a cooling unit, a fluid distribution unit, a fluid collection unit, and a set of fluid pipes to connect the cooling unit, the fluid distribution unit, and the fluid collection unit, the fluid distribution unit to receive the cooling fluid from a fluid ingress port of the set of connectors and distribute the cooling fluid through a fluid pipe to the cooling unit for thermal management of the semiconductor die using the cooling fluid, and the fluid collection unit to collect heated cooling fluid through a fluid pipe from the cooling unit, and send the heating cooling fluid to a fluid egress port of the set of connectors.

The system may also include a controller electrically or optically coupled to the internal cooling component, the controller to instruct the internal cooling component to remove cooling fluid from the electronic cooling cartridge to allow removal of the electronic cooling cartridge from the physical interface, or the controller to instruct the internal cooling component to add cooling fluid to the electronic cooling cartridge after insertion of the electronic cooling cartridge into the physical interface.

In one example, a system, includes a system device for a modular computing and cooling system, the system device includes an interconnect fabric to communicate control and data signals.

The system also includes a system device for a modular computing and cooling system, the system device includes a cooling distribution unit to distribute cooling fluid.

The system also includes a system device for a modular computing and cooling system, the system device includes a cooling network unit connected to the cooling distribution unit by a fluid pipe, the cooling network unit includes a physical interface to the cooling distribution unit; a set of platform devices for insertion into the cooling network unit and removal from the cooling network unit, a platform device from the set of platform devices includes a set of electronic cooling cartridges, an electronic cooling cartridge from the set of electronic cooling cartridges includes an internal electronic component, an internal cooling component for thermal management of the internal electronic component using the cooling fluid from the cooling distribution unit, a set of internal connectors to connect the internal electronic component to the interconnect fabric and the internal cooling component to the cooling distribution unit, and a closed container encapsulating the internal electronic component, the internal cooling component, and the set of internal connectors.

The system may also include the internal electronic component includes a semiconductor die mounted on a substrate.

The system may also include the internal cooling component includes a cooling unit for a semiconductor die, the cooling unit includes a liquid cooling component of a liquid cooling system.

The system may also include the internal cooling component includes a cooling unit, a fluid distribution unit, a fluid collection unit, and a set of fluid pipes to connect the cooling unit, the fluid distribution unit, and the fluid collection unit, the fluid distribution unit to receive the cooling fluid from a fluid ingress port of the set of connectors and distribute the cooling fluid through a fluid pipe to the cooling unit for thermal management of the semiconductor die using the cooling fluid, and the fluid collection unit to collect heated cooling fluid through a fluid pipe from the cooling unit, and send the heating cooling fluid to a fluid egress port of the set of connectors.

The system may also include a controller electrically or optically coupled to the internal cooling component, the controller to instruct the internal cooling component to remove cooling fluid from the electronic cooling cartridge to allow removal of the electronic cooling cartridge from the physical interface, or the controller to instruct the internal cooling component to add cooling fluid to the electronic cooling cartridge after insertion of the electronic cooling cartridge into the physical interface.

In one example, a method, includes detecting insertion of an electronic cooling cartridge in a physical interface for a modular computing and cooling system, the electronic cooling cartridge includes a closed container encapsulating an internal electronic component and an internal cooling component for thermal management of the internal electronic component using a cooling fluid, initializing the internal electronic component for operation with an external electronic component through an internal operational connector of the electronic cooling cartridge, and generating a system management command to send the cooling fluid from an external cooling component to the internal cooling component through a fluid pipe and an internal fluid connector of the electronic cooling cartridge.

The method also includes detecting the internal cooling component has received the cooling fluid.

The method also includes generating a system management command to start operations of the internal electronic component.

The method may also include receiving sensor measurements for the internal cooling component, determining whether adjustments are needed for the cooling fluid of the internal cooling component based on the sensor measurements, and generating a system management command to adjust the cooling fluid for the internal cooling component in accordance with the determination.

The method may also include receiving a system management command includes a request to remove the electronic cooling cartridge from the physical interface, generating a system management command to terminate operation of the internal electronic component of the electronic cooling cartridge, generating a system management command to drain the cooling fluid from the electronic cooling cartridge through the fluid pipe and the internal fluid connector of the electronic cooling cartridge, detecting operation of the internal electronic component is terminated and the cooling fluid is drained from the electronic cooling cartridge, and generating a system management command includes an authorization to remove the electronic cooling cartridge from the physical interface in response to the request.

The method may also include generating an authorization signal representing the authorization to remove the electronic cooling cartridge from the physical interface, and displaying a message by a user interface for the electronic cooling cartridge, activating a semiconductor device mounted on the closed container, or unlocking the electronic cooling cartridge from the physical interface.

The method may also include where the adjustments comprise adjusting an amount of the cooling fluid or a type of the cooling fluid.

What is claimed is:

1. An apparatus, comprising:
a physical interface for a modular computing and cooling system;
an electronic cooling cartridge for insertion into the physical interface and removal from the physical interface, the electronic cooling cartridge comprising:
an internal electronic component;
an internal cooling component for thermal management of the internal electronic component using a cooling fluid;
a set of internal connectors to connect the internal electronic component and the internal cooling component to an external electronic component and an external cooling component, respectively, of the modular computing and cooling system; and
a closed container encapsulating the internal electronic component, the internal cooling component, and the set of internal connectors.

2. The apparatus of claim 1, the physical interface to physically connect the electronic cooling cartridge to a computing and cooling system comprising a chassis housing the external electronic component and the external cooling component.

3. The apparatus of claim 1, the internal electronic component comprising a semiconductor die mounted on a substrate.

4. The apparatus of claim 1, the internal cooling component comprising a cooling unit for a semiconductor die, the cooling unit comprising a liquid cooling component of a liquid cooling system.

5. The apparatus of claim 1, the internal cooling component comprising a cooling unit, a fluid distribution unit, and a fluid pipe to connect the cooling unit and the fluid distribution unit, the fluid distribution unit to receive the cooling fluid from a fluid ingress port of the set of connectors and distribute the cooling fluid through the fluid pipe to the cooling unit for thermal management of the semiconductor die using the cooling fluid.

6. The apparatus of claim 1, the internal cooling component comprising a cooling unit, a fluid distribution unit, a fluid collection unit, and a set of fluid pipes to connect the cooling unit, the fluid distribution unit, and the fluid collection unit, the fluid distribution unit to receive the cooling fluid from a fluid ingress port of the set of connectors and distribute the cooling fluid through a fluid pipe to the cooling unit for thermal management of the semiconductor die using the cooling fluid, and the fluid collection unit to collect heated cooling fluid through a fluid pipe from the cooling unit, and send the heating cooling fluid to a fluid egress port of the set of connectors.

7. The apparatus of claim 1, comprising a sensor to measure a physical characteristic of the electronic cooling cartridge.

8. The apparatus of claim 1, comprising a controller electrically or optically coupled to the internal cooling component, the controller to instruct the internal cooling component to remove cooling fluid from the electronic cooling cartridge to allow removal of the electronic cooling cartridge from the physical interface, or the controller to instruct the internal cooling component to add cooling fluid to the electronic cooling cartridge after insertion of the electronic cooling cartridge into the physical interface.

9. The apparatus of claim 1, the physical interface comprising a cartridge base to physically connect the electronic cooling cartridge and a cooling network unit of the modular computing and cooling system.

10. A system, comprising:
a platform device for a modular computing and cooling system, the platform device comprising:
an interconnect fabric to communicate control and data signals;
a cooling distribution unit to distribute cooling fluid;
a cooling network unit connected to the cooling distribution unit by a fluid pipe, the cooling network unit comprising a physical interface to the cooling distribution unit;
a set of electronic cooling cartridges for insertion into the cooling network unit and removal from the cooling network unit, an electronic cooling cartridge from the set of electronic cooling cartridges comprising:
an internal electronic component;
an internal cooling component for thermal management of the internal electronic component using the cooling fluid from the cooling distribution unit;
a set of internal connectors to connect the internal electronic component to the interconnect fabric and the internal cooling component to the cooling distribution unit; and
a closed container encapsulating the internal electronic component, the internal cooling component, and the set of internal connectors.

11. The system of claim 10, the cooling network unit to physically connect the set of electronic cooling cartridges to a computing and cooling system comprising a chassis housing the interconnect fabric, the cooling distribution unit, and the cooling network unit.

12. The system of claim 10, the internal electronic component comprising a semiconductor die mounted on a substrate.

13. The system of claim 10, the internal cooling component comprising a cooling unit for a semiconductor die, the cooling unit comprising a liquid cooling component of a liquid cooling system.

14. The system of claim 10, the internal cooling component comprising a cooling unit, a fluid distribution unit, a fluid collection unit, and a set of fluid pipes to connect the cooling unit, the fluid distribution unit, and the fluid collection unit, the fluid distribution unit to receive the cooling fluid from a fluid ingress port of the set of connectors and distribute the cooling fluid through a fluid pipe to the cooling unit for thermal management of the semiconductor die using the cooling fluid, and the fluid collection unit to collect heated cooling fluid through a fluid pipe from the cooling unit, and send the heating cooling fluid to a fluid egress port of the set of connectors.

15. The system of claim 10, comprising a controller electrically or optically coupled to the internal cooling component, the controller to instruct the internal cooling component to remove cooling fluid from the electronic cooling cartridge to allow removal of the electronic cooling cartridge from the physical interface, or the controller to instruct the internal cooling component to add cooling fluid to the electronic cooling cartridge after insertion of the electronic cooling cartridge into the physical interface.

16. A method, comprising:
detecting insertion of an electronic cooling cartridge in a physical interface for a modular computing and cooling system, the electronic cooling cartridge comprising a closed container encapsulating an internal electronic component and an internal cooling component for thermal management of the internal electronic component using a cooling fluid;
initializing the internal electronic component for operation with an external electronic component through an internal operational connector of the electronic cooling cartridge; and
generating a system management command to send the cooling fluid from an external cooling component to the internal cooling component through a fluid pipe and an internal fluid connector of the electronic cooling cartridge;
detecting the internal cooling component has received the cooling fluid; and
generating a system management command to start operations of the internal electronic component.

17. The method of claim 16, comprising:
receiving sensor measurements for the internal cooling component;
determining whether adjustments are needed for the cooling fluid of the internal cooling component based on the sensor measurements; and
generating a system management command to adjust the cooling fluid for the internal cooling component in accordance with the determination.

18. The method of claim 17, wherein the adjustments comprise adjusting an amount of the cooling fluid or a type of the cooling fluid.

19. The method of claim 16, comprising:
receiving a system management command comprising a request to remove the electronic cooling cartridge from the physical interface;
generating a system management command to terminate operation of the internal electronic component of the electronic cooling cartridge;
generating a system management command to drain the cooling fluid from the electronic cooling cartridge through the fluid pipe and the internal fluid connector of the electronic cooling cartridge;
detecting operation of the internal electronic component is terminated and the cooling fluid is drained from the electronic cooling cartridge; and
generating a system management command comprising an authorization to remove the electronic cooling cartridge from the physical interface in response to the request.

20. The method of claim 16, comprising:
generating an authorization signal representing the authorization to remove the electronic cooling cartridge from the physical interface; and
displaying a message by a user interface for the electronic cooling cartridge;
activating a semiconductor device mounted on the closed container; or
unlocking the electronic cooling cartridge from the physical interface.
